(19) United States
(12) Patent Application Publication
(10) Pub. No.: US 2021/0193857 A1
(43) Pub. Date: Jun. 24, 2021

(54) LAYERED LUMINESCENT SOLAR CONCENTRATORS

(71) Applicant: University of Washington, Seattle, WA (US)

(72) Inventors: Daniel R. Gamelin, Seattle, WA (US); Theodore Cohen, Seattle, WA (US); Daniel M. Kroupa, Seattle, WA (US); Matthew J. Crane, Seattle, WA (US); John Devin Mackenzie, Seattle, WA (US); Christine Keiko Luscombe, Seattle, WA (US); Tyler J. Milstein, Seattle, WA (US)

(73) Assignee: University of Washington, Seattle, WA (US)

(21) Appl. No.: 17/257,846

(22) PCT Filed: Jul. 3, 2019
(86) PCT No.: PCT/US2019/040624

§ 371 Date: Jan. 4, 2021

Related U.S. Application Data
(60) Provisional application No. 62/694,195, filed on Jul. 5, 2018.

(51) Int. Cl. H01L 31/055; C09K 11/77; C09K 11/62

(52) U.S. Cl. CPC H01L 31/055; C09K 11/621; C09K 11/7705

(57) ABSTRACT

The present disclosure features a luminescent solar concentrator, including a layer including a quantum-cutting material; and a layer including a broadly light-absorbing material (that is also photoluminescent) optically coupled to and beneath the layer including the quantum-cutting material, relative to a light source.

### CROSS-REFERENCE(S) TO RELATED APPLICATION(S)

This application claims the benefit of U.S. Provisional Application No. 62/694,195, filed Jul. 5, 2018, the disclosure of which is incorporated herein by reference in its entirety.

### STATEMENT OF FEDERALLY SPONSORED RESEARCH AND DEVELOPMENT

This invention was made with government support under Grant Nos. DMR1035512 and DMR1206221 and DMR1505901 and DMR1719797 and DMR1807394, awarded by the National Science Foundation. The government has certain rights in the invention.

### BACKGROUND

A luminescent solar concentrator (LSC) collects and concentrates sunlight for use in solar power generation. LSC is a device that typically includes a planar waveguide coated or impregnated with a luminophore. Sunlight absorbed by the luminophore coated on or contained within the waveguide is re-emitted into the waveguide, where it is captured by total internal reflection, which causes it to travel to the edges to be concentrated for use by a light-utilization device, such as a photovoltaic cell (PV). Unlike lens- and mirror-based concentrators, which require tracking systems to follow the sun's motion and can only concentrate direct, specular sunlight, a LSC is a passive device that works equally well with both diffuse and specular sunlight. It is therefore less costly to build, install, and maintain, more easily integrated into the built environment or portable solar energy systems, more damage tolerant, and can be used in climates where there is little direct sunlight. Furthermore, because a LSC can produce wavelength-to-bandgap matched photons by downshifting, there is reduced need for PV cooling.

Thus, a LSC can be used to capture diffuse solar radiation from a large physical area and direct the energy to a light-utilization device, such as small photovoltaic cells that generate current. Solar radiation is transmitted into an optically clear waveguide and is absorbed by a luminescent material embedded in a waveguide. The luminescent material emits in all directions and most of the emitted light is trapped in the waveguide via total internal reflection. Once trapped, the emitted light is transmitted through the waveguide to light-utilization devices (e.g., photovoltaic cells) that are optically coupled to its edges. This means that it can generate electricity using a significantly smaller area of active photovoltaic cells than would normally be required to generate equivalent power without luminescent solar concentration.

For such a device to operate effectively, the luminescent material must emit a high proportion of the photons it absorbs. This property is summarized by photoluminescence quantum yield (PLQY), which is defined as the ratio of emitted to absorbed photons. The luminescent material must also have an emission energy that is significantly lower that the onset of its absorption. This property is summarized by effective Stokes shift, which is defined as the energy difference between the photoluminescent peak energy and the absorption onset of the material. If the effective Stokes shift is too low, the performance of an LSC is reduced by reabsorption of the transmitted light by the luminescent material. Reabsorption reduces the amount of light that can be collected by the optically coupled PV and has been shown to significantly compromise the potential efficiency of large LSCs. The LSC can contain luminescent materials that absorb a large fraction of the solar spectrum.

LSCs have been intensively researched for decades because they can concentrate diffuse light with potentially unlimited flux gains (ratio of photons converted by a given LSC-coupled PV to photons that would be converted by the same PV exposed directly to the same solar flux) using a collection waveguide fabricated from relatively low cost and low energy-to-manufacture per unit area materials. Recent models suggest that 100,000 square kilometers of conventional dense-cell solar-panel area would be required to meet current energy demands. With an energy pay-back period for silicon PV that will likely remain on the order of several years, LSCs are well suited to reduce the total area of silicon PV cells required to meet energy demands. Thus, LSCs, such as those including nanocrystals, represent a promising clean-energy technology capable of concentrating direct and diffuse light to reduce the area of photovoltaic (PV) cells—which are energetically costly to manufacture—required to meet energy demands.

Most early work with LSCs used organic dyes as luminophores, and these LSCs have been implemented in a variety of large-scale installations. Recently, several inorganic semiconductor nanocrystals (NCs) with high PLQYs have been explored for LSC applications, including various simple luminescent NCs, as well as more complicated NC structures such as core/shell NCs, dot-in-rod NCs, and a variety of impurity- or defect-activated NCs. Such semiconductor NCs can be made with less reabsorption of their own emission, larger absorption cross-sections, greater photochemical stability, and broader solar absorption than organic dyes. A survey of several leading NCs showed that Mn²⁺-doped and Cu⁺-doped NCs have substantially less intrinsic reabsorption than heterostructured NCs. CuInE₂ (E=S, Se) NCs have similar PL characteristics as Cu⁺-doped NCs and can be made with higher PLQYs. Consequently, LSCs based on CuInE₂ NCs have been heavily investigated and are currently being commercialized by UbiQD Inc.

Beyond Mn²⁺ and Cu⁺, Yb³⁺ has been targeted as a NC dopant of particular interest for LSCs because its ²F_{5/2}→²F_{7/2} f-f transition combines a narrow PL lineshape with high PLQYs and low f-f oscillator strengths (low reabsorption) at energies only slightly above the silicon band gap. Several LSC designs employing Yb³⁺ luminescence have been reported, but the luminophores used to date have lower absorption cross sections than organic dyes or inorganic NCs. Attempts at sensitizing Yb³⁺ luminescence using intermediate-gap semiconductor NCs have been moderately successful, but none of these materials were sufficiently promising until the recent development of Yb³⁺:CsPbX₃ perovskite NCs, which show highly efficient picosecond quantum-cutting that generates PLQYs approaching the quantum-cutting limit of 200%.

Although quantum-cutting Yb³⁺-doped CsPbX₃ NCs have reabsorption-minimizing effective Stokes shifts and unprecedented PLQYs for doped NCs, the energy-conservation requirement of quantum-cutting limits their solar absorption to λ<˜500 nm. This limitation mirrors the challenges faced by high-band-gap PV materials, which have therefore emerged as candidates for alternative configurations including tandem or multi junction PV cells. The tandem concept has been explored in LSCs based on organic or inorganic luminophores, where a top LSC coupled to a wider-gap PV is placed above a separate bottom LSC coupled to a lower-gap PV and the PV voltages are summed, allowing bluer photons to be converted with greater energy efficiency than in a single-layer LSC. Two-terminal tandem devices require near-perfect photocurrent matching between the top and bottom cells under all operating conditions to prevent the closed-circuit current from being limited by the lowest performing PV cell, however. Photocurrent losses are observed even in state-of-the-art two-terminal tandem PV cells, and this challenge has not been addressed by existing tandem LSCs.

There is a need for LSCs that minimize photocurrent losses, for example, when the LSCs are used in conjunction with PVs. The present disclosure seeks to fulfill this need and provides further related advantages.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

In one aspect, the present disclosure features a luminescent solar concentrator, including a layer including a quantum-cutting material; and a layer including a broadly light-absorbing material optically coupled to and beneath the layer including the quantum-cutting material, wherein the broadly light-absorbing material has a red-shifted absorption onset compared to the absorption onset of the quantum-cutting material.

In another aspect, the present disclosure features an article including the luminescent solar concentrator of the present disclosure. The article can be, for example, a window pane, a coating, and/or an electronic display.

### DESCRIPTION OF THE DRAWINGS

The foregoing aspects and many of the attendant advantages of this disclosure will become more readily appreciated as the same become better understood by reference to the following detailed description, when taken in conjunction with the accompanying drawings, wherein:

FIG. 1A is an illustration of a conventional tandem luminescent solar concentrator.

FIG. 1B is an illustration of an embodiment of a luminescent solar concentrator of the disclosure.

FIG. 2 is a cross-sectional illustration of an embodiment of a luminescent solar concentrator of the present disclosure.

FIG. 3 is a cross-sectional illustration of an embodiment of a luminescent solar concentrator of the present disclosure.

FIG. 4A is an absorption and normalized photoluminescence (PL) spectra of Yb³⁺:CsPbCl₃ nanocrystals (NCs) plotted with the external quantum efficiency (EQE) of a near-infrared enhanced Si HIT photovoltaic and the AM1.5 solar spectrum (shaded area). Spectra were collected at room temperature.

FIG. 4B is a transmission electron micrograph of a representative sample of Yb³⁺:CsPbCl₃ nanocrystals.

FIG. 4C is an X-ray diffraction data for a representative sample of Yb³⁺:CsPbCl₃ nanocrystals.

FIG. 5A is normalized photoluminescence spectra of Yb³⁺:CsPbCl₃ nanocrystals suspended in hexane with ODₜ˜0.75 mm⁻¹ at 375 nm, obtained from a 1D LSC at various excitation distances relative to the edge-mounted photodetector (inset). The absorption spectrum of the hexane solvent is also shown.

FIG. 5B is a graph of the integrated normalized Yb³⁺:CsPbCl₃ nanocrystal photoluminescence intensity plotted as a function of excitation distance away from the photodetector, for nanocrystals in hexane with ODₜ˜0.75 mm⁻¹ (triangles) and ODₜ˜0.075 mm⁻¹ (circles) at 375 nm. The reabsorption probability modeled with hexane absorption from FIG. 5A is shown. The experimentally determined performance limit of the 1D LSC is also shown as a solid line (labeled waveguide losses). All photoluminescence data were collected with excitation at 375 nm, and all data were collected at room temperature.

FIG. 6A shows the photoluminescence intensity of Yb³⁺:CsPbCl₃ nanocrystals suspended in tetrachloroethylene (TCE) from a 1D LSC experiment plotted from low excitation distances to high excitation distance with the corrected absorption spectrum of TCE.

FIG. 6B shows the integrated normalized photoluminescence intensity of Yb³⁺:CsPbCl₃ NCs plotted as a function of excitation distance for solutions in hexane with an ODₜ˜0.075 mm⁻¹ and in TCE with an ODₜ˜0.075 mm⁻¹. The solid line is the experimentally determined performance limit of the 1D LSC. The analytical atomic Yb³⁺ concentration for these nanocrystals was 4.6% and the PLQY was 138% in hexane and 71% after transfer to TCE.

FIG. 7A shows the absorption spectrum of hexane, a representative PMMA sample, and Schott optical-quality glass overlaid with the normalized PL spectrum of Yb³⁺:CsPbCl₃ nanocrystals (right pointing arrow). The PMMA spectrum was obtained by subtracting experimental spectra measured for two samples with different thickness to eliminate surface reflection and scattering effects.

FIG. 7B shows the normalized photoluminescence intensity of Yb³⁺:CsPbCl₃ nanocrystals in hexane as a function of excitation distance in a 120 cm-long 1D LSC (dots). The curves plot absorption probabilities for the Yb³⁺:CsPbCl₃ nanocrystal photoluminescence waveguided through glass (top line and PMMA (bottom curve) calculated using equation 1 below. The intermediate traces show the absorption probabilities in hypothetical mixed PMMA/glass waveguides with volume percentages increasing from 0% to 100% by increments of 20%.

FIG. 8A shows an illustration of an embodiment of a monolithic bilayer LSC of the present disclosure. The top layer contains quantum-cutting nanocrystals (e.g., Yb³⁺:CsPb(Cl₁₋ₓBrₓ)₃ nanocrystals) and the bottom layer contains broadly light-absorbing nanocrystals (e.g., CulnS₂ nanocrystals).

FIG. 8B shows the absorption and normalized photoluminescence spectra of Yb³⁺:CsPbCl₃ nanocrystals and CulnS₂/ZnS nanocrystals overlaid with the AM 1.5 solar spectrum (shaded area) and the external quantum efficiency (EQE) of a near-IR enhanced Si HIT photoluminescence.

FIG. 8C is a graph of the projected 2D flux gain of a Yb³⁺:CsPbCl₃ nanocrystal LSC, a CuInS₂/ZnS nanocrystal LSC, and the monolithic bilayer device shown in FIG. 8A.

FIG. 9A shows the absorption and normalized photoluminescence spectra of Yb³⁺:CsPb(Cl₁₋ₓBrₓ)₃ nanocrystals with x˜0.75 and CuInS₂/ZnS nanocrystals overlaid with the AM 1.5 solar spectrum (shaded area) and the external quantum efficiency (EQE) of a near-infrared (NIR) enhanced Si HIT PV.

FIG. 9B is a graph of the projected 2D flux gain of a Yb³⁺:CsPb(Cl₁₋ₓBrₓ)₃ nanocrystal LSC at various x levels, a CuInS₂/ZnS nanocrystal LSC, and the monolithic, bilayer device shown in FIG. 8A. The absorption onset of the Yb³⁺:CsPb(Cl₁₋ₓBrₓ)₃ nanocrystals is varied linearly from 412 nm to 488 nm for the three plotted traces.

FIG. 10A shows the photoluminescence spectra of Yb³⁺:CsPbCl₃ nanocrystals with ODₜ˜0.75 mm⁻¹ at 375 nm. Spectra were collected at various excitation distances in the 120 cm 1D LSC.

FIG. 10B shows the photoluminescence spectra of Yb³⁺:CsPbCl₃ nanocrystals with ODₜ˜0.075 mm⁻¹ at 375 nm, suspended in hexane. Spectra were collected at various excitation distances in the 120 cm 1D LSC.

FIG. 10C shows the normalized photoluminescence spectra of Yb³⁺:CsPbCl₃ nanocrystals with ODₜ˜0.075 mm⁻¹ at 375 nm suspended in hexane.

FIG. 10D shows the normalized photoluminescence spectra of Yb³⁺:CsPbCl₃ NCs with ODₜ˜0.075 mm⁻¹ at 375 nm suspended in TCE, collected at different excitation distances in the 1D LSC. The insets show the color coding with distance.

FIG. 11 shows the absorption spectra of the Yb³⁺:CsPbCl₃ nanocrystals. The dashed trace (Hexanes (mm⁻¹)) corresponds to the triangles reported in FIG. 5B, the solid trace (Hexanes (cm⁻¹)) corresponds to the circles reported in FIG. 5B, and the solid trace (TCE (cm⁻¹)) corresponds to the nanocrystals in TCE shown in FIG. 6A.

FIG. 12 shows the waveguide attenuation plotted as photoluminescence intensity vs. excitation distance. The curve shows the result of fitting the data using equation 1, with a wavelength independent extinction coefficient of 0.002 cm⁻¹.

### DETAILED DESCRIPTION

Certain compounds, such as Yb³⁺-doped CsPb(Cl₁₋ₓBrₓ)₃ perovskite nanocrystals (NCs) can convert single high-energy photons into pairs of low-energy photons, generating photoluminescence quantum yields greater than 100% and approaching 200%. This process—known as quantum-cutting—can improve LSC efficiencies by simultaneously eliminating reabsorption and thermalization losses. The present disclosure describes a fundamentally new monolithic multilayer LSC device architecture that utilizes the unique spectral properties of quantum-cutting Yb³⁺-doped CsPb(Cl₁₋ₓBrₓ)₃ NCs by pairing them with a narrower-gap LSC layer to enhance solar absorption within a single waveguide. The LSC architectures of the present disclosure overcomes a major limitation of conventional two-terminal tandem LSCs by decreasing the need for current matching, and leads to marked performance improvements.

In one aspect, the present disclosure features a luminescent solar concentrator, including a layer including a quantum-cutting material; and a layer including a broadly light-absorbing material (that is also photoluminescent) optically coupled to and beneath the layer including the quantum-cutting material, relative to a light source. Thus, when the luminescent is exposed to a light source, the layer including the quantum-cutting material is first exposed to the incident light from the light source, and the layer including the broadly light-absorbing material encounters the incident light next. The broadly light-absorbing material has a red-shifted absorption onset compared to the absorption onset of the quantum-cutting material. The layers each include at least one major surface. The layers each include at least one minor surface (e.g., an edge). The layers that include the different luminophores (e.g., the quantum-cutting material and the broadly light-absorbing material) together form a single monolithic structure that is optically coupled to a light-utilization device, for example, at the edge of the monolithic structure.

As used herein, with regard to planar luminescent solar concentrators, the planar surface is sometimes referred to as a “major surface” of the LSC or the waveguide of the LSC. A planar LSC has two major surfaces having large surface areas (e.g., a top and bottom surface). A planar LSC has minor surfaces at the edges having smaller surface areas compared to the major surfaces. In a LSC based on a planar waveguide, light from the luminophores (e.g., the quantum-cutting material, and/or the broadly light-absorbing material) is collected by a light-utilization device (e.g., a photovoltaic cell) in optical communication with the minor surfaces (e.g., the edges) of the LSC's planar waveguide.

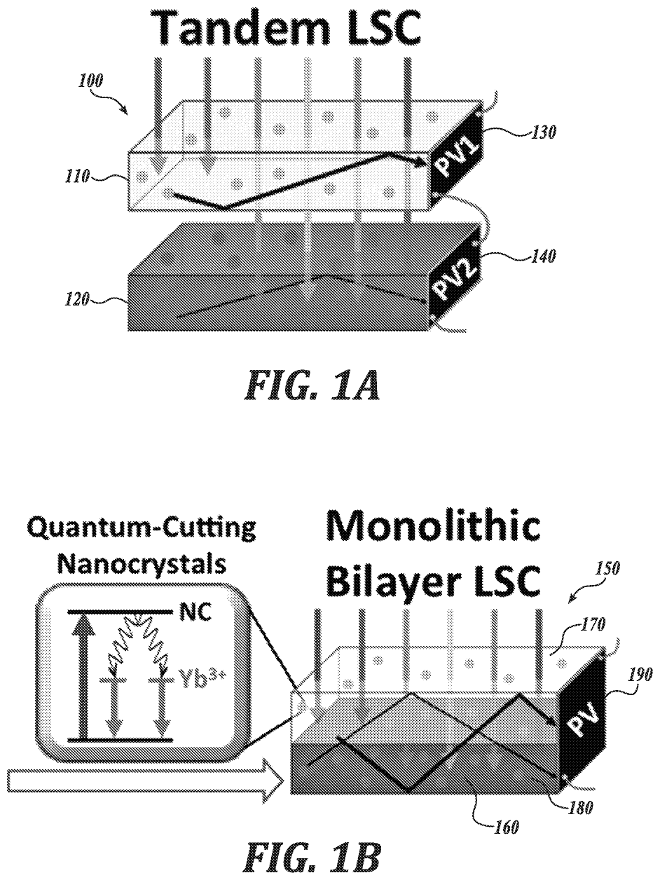

Referring to FIG. 1A, a conventional tandem LSC 100 includes separate and discrete LSCs, such as 110 and 120, that each absorbs a portion of an incident light, and that each redirects the light in its own waveguide to photovoltaic devices 130 and 140 that are individually coupled to each of the LSCs. In contrast, referring to FIG. 1B, the present disclosure describes a LSC 150 that is a monolithic and multilayered, having a single waveguide 160 that includes layers (e.g., 170 and 180), each having different luminophores, and coupled to a light-utilization device 190 (e.g., a photovoltaic device). In some embodiments, the number of coupled light-utilization devices is fewer than the number of layers of the LSC. In some embodiments, the monolithic LSC is coupled to a single light-utilization device.

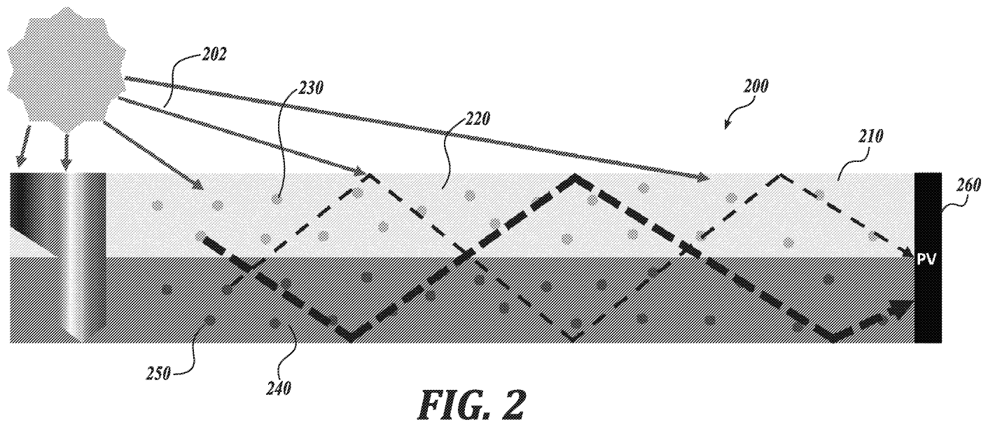

As shown in FIG. 2, in an exemplary LSC of the present disclosure, a top face of the waveguide 210 of LSC 200 is exposed to diffuse incident light, such as solar radiation. When the diffuse incident light 202 is coupled to waveguide 210, the top layer 220 containing the quantum-cutting material 230 absorbs higher energy light with wavelengths below the absorption threshold of the quantum-cutting material. The remaining lower energy light is transmitted through the first layer and is absorbed by the broadly light-absorbing material 250 of bottom layer 240. The LSC can absorb most of the visible light spectrum. Both luminophores (the quantum-cutting material 230 and the broadly light-absorbing material 250) emit light that is transmitted through waveguide 210 via total internal reflection to light-utilization device 260 coupled to the edges of LSC 200.

In some embodiments, the quantum-cutting materials emits at a rate that is almost twice (e.g., about 1.6 times, about 1.7 times, about 1.8 times, or about 1.9 times) the absorption rate. In some embodiments, the emission spectrum for the quantum-cutting material and the broadly light-absorbing photoluminescence do not significantly overlap with the absorption spectra of either material (e.g., overlap by less than 20%, less than 10% or less than 5% of their normalized emission and absorption spectra), so reabsorption losses for the monolithic tandem-like layer device are minimized. The quantum-cutting process can convert light that is poorly absorbed by the light-utilization device into light that is better optimized for the desired use, such as for electrical current generation. By generating more photons (PLQY>100%), the quantum-cutting materials can achieve high energy conversion efficiencies while still providing large effective luminescence Stokes shifts.

### Definitions

Example devices, methods, and systems are described herein. It should be understood the words “example,” “exemplary,” and “illustrative” are used herein to mean “serving as an example, instance, or illustration.” Any embodiment or feature described herein as being an “example,” being “exemplary,” or being “illustrative” is not necessarily to be construed as preferred or advantageous over other embodiments or features. The example embodiments described herein are not meant to be limiting. It will be readily understood aspects of the present disclosure, as generally described herein, and illustrated in the figures, can be arranged, substituted, combined, separated, and designed in a wide variety of different configurations, all of which are explicitly contemplated herein.

Furthermore, the particular arrangements shown in the Figures should not be viewed as limiting. It should be understood other embodiments may include more or less of each element shown in a given Figure. Further, some of the illustrated elements may be combined or omitted. Yet further, an example embodiment may include elements not illustrated in the Figures. As used herein, with respect to measurements, “about” means +/−5%.

As used herein, a recited range includes the end points, such that from 0.5 mole percent to 99.5 mole percent includes both 0.5 mole percent and 99.5 mole percent.

As used herein, “photoluminescent” refers to light emission from a material after the absorption of photons and encompasses fluorescence and phosphorescence.

As used herein, “nanocrystal” refers to a crystal having its largest dimension smaller than or equal to about 100 nm, and composed of atoms in a crystalline arrangement.

As used herein, “nanoparticle” refers to a particle having its largest dimension smaller than or equal to about 100 nm.

As used herein, “semiconductor” refers to a material that has a band gap energy that overlaps with the spectrum of solar radiation at the Earth's surface. In general, a semiconductor has a band gap between that of a metal and that of an insulator, although it is appreciated that there is no rigorous distinction between insulators and wide-gap semiconductors.

As used herein, “defect” or “dopant” refers to a crystallographic defect, where the arrangement of atoms or molecules in a crystalline material departs from perfection by addition or exclusion of an ion, impurity atom, or small clusters of ions or atoms. The defect can occur at a single lattice point in the form of a vacancy, an interstitial defect, or an impurity. In some embodiments, the crystalline lattice has small clusters of atoms that form a separate phase (i.e., a precipitate).

As used herein, light of shorter wavelength is considered “blue,” “bluer,” or “blue-shifted” when compared to light of a longer wavelength, which is “red,” “redder,” or “red-shifted,” even if the specific wavelengths compared are not technically blue or red.

As used herein, “average maximum dimension” refers the average maximum length of a nanoparticle or nanocrystal, obtained by measuring a maximum dimension (along any given direction) of each nanoparticle or nanocrystal in an ensemble of nanoparticles or nanocrystals, and averaged amongst the measured nanoparticles or nanocrystals. The dimension can be measured by various techniques including transmission electron microscopy or scanning electron microscopy, and the ensemble of nanoparticles or nanocrystals used for this determination typically includes at least 100 nanocrystals.

As used herein, “surface roughness” refers the average root-mean-squared deviation in the height of a surface over an area of approximately 100 microns.

As used herein, “optical quantum efficiency” (OQE) refers to the fraction of incident photons absorbed by the photoluminescent species (e.g., nanoparticles) in an LSC that is emitted from the concentrator edge.

As used herein, “photoluminescence quantum yield” (PLQY) or “quantum yield” (QY) refer to the ratio of the number of emitted photons per number of absorbed photons.

The particulars shown herein are by way of example and for purposes of illustrative discussion of the preferred embodiments of the present invention only and are presented in the cause of providing what is believed to be the most useful and readily understood description of the principles and conceptual aspects of various embodiments of the invention. In this regard, no attempt is made to show structural details of the invention in more detail than is necessary for the fundamental understanding of the invention, the description taken with the drawings and/or examples making apparent to those skilled in the art how the several forms of the invention may be embodied in practice.

As used herein and unless otherwise indicated, the terms “a” and “an” are taken to mean “one”, “at least one” or “one or more”. Unless otherwise required by context, singular terms used herein shall include pluralities and plural terms shall include the singular.

Unless the context clearly requires otherwise, throughout the description and the claims, the words ‘comprise’, ‘comprising’, and the like are to be construed in an inclusive sense as opposed to an exclusive or exhaustive sense; that is to say, in the sense of “including, but not limited to”. Words using the singular or plural number also include the plural and singular number, respectively. Additionally, the words “herein,” “above,” and “below” and words of similar import, when used in this application, shall refer to this application as a whole and not to any particular portions of the application.

The description of embodiments of the disclosure is not intended to be exhaustive or to limit the disclosure to the precise form disclosed. While the specific embodiments of, and examples for, the disclosure are described herein for illustrative purposes, various equivalent modifications are possible within the scope of the disclosure, as those skilled in the relevant art will recognize.

All of the references cited herein are incorporated by reference. Aspects of the disclosure can be modified, if necessary, to employ the systems, functions, and concepts of the above references and application to provide yet further embodiments of the disclosure. These and other changes can be made to the disclosure in light of the detailed description.

Specific elements of any foregoing embodiments can be combined or substituted for elements in other embodiments. Moreover, the inclusion of specific elements in at least some of these embodiments may be optional, wherein further embodiments may include one or more embodiments that specifically exclude one or more of these specific elements. Furthermore, while advantages associated with certain embodiments of the disclosure have been described in the context of these embodiments, other embodiments may also exhibit such advantages, and not all embodiments need necessarily exhibit such advantages to fall within the scope of the disclosure.

### Luminescent Solar Concentrators

The luminescent solar concentrator of the present disclosure can include one or more layers. The layers can each independently include a waveguide material, and each layer can be optically coupled immediately adjacent layer(s). In some embodiments, the LSC can include a waveguiding material in each layer, or in one or more layers, that is spectroscopically innocent at a wavelength range spanning the solar radiation spectrum. The waveguide material can include a polyacrylate, a polycarbonate, a glass (e.g., an inorganic glass), a quartz, a polycrystalline solid, an amorphous solid, a fluorinated polymer (e.g., a cyclic perfluorinated polyether, CYTOP), a polysilicone, a polysiloxane, a polyalkylacrylate, and/or a cyclic olefin. In some embodiments, the luminescent solar concentrator can further include a layer such as a bragg, short-pass, long-pass, and/or broadband mirror, so as to decrease the likelihood of escape of light emitted by the broadly light-absorbing layer and/or the quantum-cutting layer through some surfaces of the luminescent solar concentrator. In some embodiments, the waveguide material is spectroscopically innocent at the emission wavelengths of both the quantum-cutting material and the broadly light-absorbing materials.

The quantum-cutting material and the broadly light-absorbing material can each independently be present in the LSC in the form of particles, such as nanocrystals, or in the form of a film, such as a thin film. When the quantum-cutting material and/or the broadly light-absorbing material are in the form of particles, they can be suspended in a waveguide matrix material. When the quantum-cutting material and/or the broadly light-absorbing material is in the form of a film, the film can have similar absorption and emission properties as a particle-infused waveguide, and can reside between two layers of spectroscopically-innocent waveguiding materials, such as glass or transparent polymer laminate. As used herein, “spectroscopically-innocent” refers to a material that does not have an attenuation coefficient above 0.0087 dB cm⁻¹ at a wavelength that overlaps with the emission of the luminophores in a LSC of the present disclosure.

As discussed above, the quantum-cutting material and the broadly light-absorbing material can be incorporated into waveguide materials for LSC applications. For example, the LSC can include the quantum-cutting material and/or the broadly light-absorbing material, each independently at a weight ratio of less than 10% (e.g., less than 8%, less than 6%, less than 4%, less than 2%, or less than 1%) and/or more than 0.01% (more than 1%, more than 4%, more than 6%, or more than 8%), relative to the waveguide material. The quantum-cutting material and/or the broadly light-absorbing material can be present in the waveguide material in a gradient, or at a uniform concentration over the volume of the waveguide material, so long as 50% or more photons with energies above the absorption onset energy of the quantum-cutting material are absorbed by the quantum-cutting material. In some embodiments, the quantum-cutting material is present in the waveguide material in a separate non-overlapping layer region compared to the broadly light-absorbing material in the waveguide material. In some embodiments, the quantum-cutting material and/or the broadly light-absorbing material is present in the waveguide material in a concentration gradient spanning a portion of the depth of the waveguide material; and/or the LSC can include an overlapping region (e.g., a transition layer) where the quantum-cutting material and the broadly light-absorbing material are both present.

The waveguide matrix can be a polyacrylate, a polycarbonate, a cyclic perfluorinated polyether, a polysilicone, a polysiloxane, a polyalkylacrylate, a cyclic olefin (e.g., Zeonex COP™ (Nippon Zeon) and Topas COC™ (Celanese AG)), crosslinked derivatives thereof, and/or copolymers thereof, wherein each of which is independently optionally substituted with a C₁₋₁₈ alkyl, C₁₋₁₈ alkenyl, aryl group, and any combination thereof. In some embodiments, the waveguide material is poly(methyl methacrylate) or poly(lauryl methacrylate), and cross-linked derivatives thereof. In some embodiments, the waveguide material is poly(lauryl methacrylate-co-ethylene glycol dimethacrylate). The waveguide matrix can be transparent.

In some embodiments, the waveguide material can be an inorganic glass, a polycrystalline solid, or an amorphous solid. Representative examples of inorganic glass, polycrystalline solid, or amorphous solid include indium tin oxide, SiO₂, ZrO₂, HfO₂, ZnO, TiO₂, fluorosilicates, borosilicates, phosphosilicates, fluorozirconates (e.g., ZBLAN (ZrF₄—BaF₂—LaF₃—AlF₃—NaF)), organically modified silicates (e.g., silica-polyethylene urethane composites, silica-polymethylmethacrylate composites, and glymo-3-glycidoxypropyltrimethoxysilane). For example, the waveguide material can be an inorganic glass, such as indium tin oxide.

The waveguide material can have a surface roughness of 2 nm or less (e.g., 1 nm or less, 0.5 nm or less, or 0.2 nm or less). Without wishing to be bound by theory, it is believed that a waveguide material having a smooth surface can minimize light scattering events.

The effects of optical losses in an LSC resulting from absorption by the waveguide material, scattering from waveguide imperfections, roughness at the surface of the waveguide, and similar non-idealities can be summarized through a waveguide attenuation coefficient, α. Different waveguide materials can possess different attenuation coefficients, and to maximize OQE, α should be as small as possible. In some embodiments, the LSC having a plurality of photoluminescent nanoparticles can have an attenuation coefficient of less than 0.05 dB/cm (less than 0.03 dB/cm, less than 0.01 dB/cm) at a wavelength corresponding to a peak emission of the quantum-cutting material and/or the broadly light-absorbing material.

In some embodiments, in addition to minimizing waveguide losses due to absorption by the waveguide material, scattering from waveguide imperfections, roughness at the surface of the waveguide, and similar non-idealities, there may be other considerations in selecting a waveguide material, such as cost or environmental lifetime. The compatibility of the photoluminescent nanoparticles with a wide range of waveguide materials as described above can enable selection of a waveguide material that is well-suited for a particular LSC application of the LSC. As an example, a large LSC can benefit from a more highly transparent waveguide material such as a polysiloxane, whereas a less transparent (but also less expensive) waveguide material such as poly(methyl methacrylate) can be used for a small LSC.

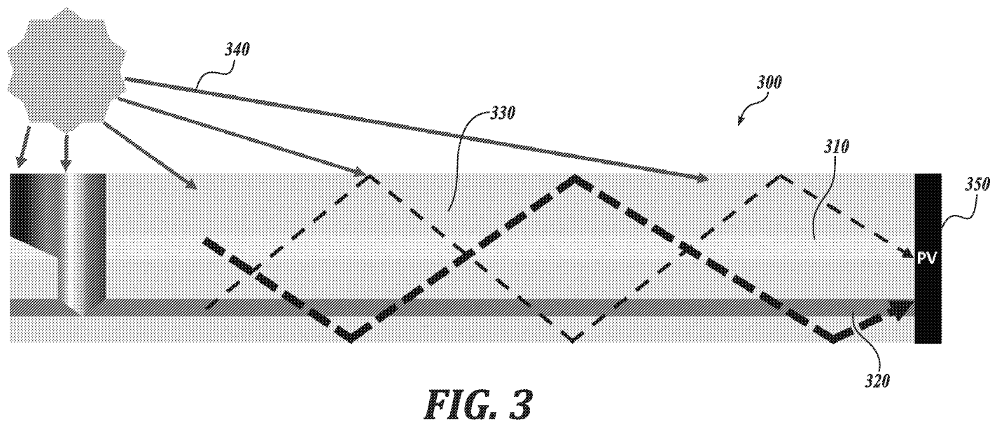

Referring to FIG. 3, an LSC 300 can include a thin film of a quantum cutting material 310 and a thin film of a broadly light-absorbing material 320. As described previously, the emission would not be absorbed by the thin films, but would be primarily transmitted through an optically clear waveguide 330. As shown in FIG. 3, the layered LSC absorbs diffuse solar radiation 340, once the solar radiation 340 is coupled into the waveguide, it is absorbed by the quantum-cutting thin film 310. Absorption by the thin film of quantum-cutting material 310 removes high energy light in the top layer and the remaining low energy light is transmitted to the bottom layer including broadly light-absorbing material 320. The low energy light transmitted to the bottom layer is absorbed by the thin film of broadly light-absorbing material 320 so that most, or all, of the visible spectrum is absorbed by the LSC. Referring again to FIG. 3, quantum-cutting thin film 310 emits at a rate that is almost twice the absorption rate at energies dictated by its photoluminescence spectrum. The broadly light-absorbing thin film 320 emits at energies dictated by its photoluminescence spectrum. The quantum-cutting thin film photoluminescence 310 and the broad light-absorbing thin film photoluminescence 310 are waveguided via total internal reflection to the photovoltaic cell 350 optically coupled to the edges of the devices.

In some embodiments, the quantum-cutting material absorbs light wavelengths below about 500 nm and emit at about 1000 nm (emission maximum). For example, the 1000 nm emission does not overlap with the absorption spectrum of a broadly light-absorbing material, such as CuInSe₂₍₁₋ₓ₎S₂ₓ (0≤x≥1), meaning that it can be used in a tandem-like device structure without the need for two or more separate waveguides. The quantum-cutting material can have high effective Stokes shifts and have PLQY up to 200% (e.g., 170%). Materials with PLQY above 100% are referred to here as quantum-cutting. In certain embodiments, the LSC can include a quantum-cutting material such as Yb³⁺:CsPbCl₃₍₁₋ₓ₎Br₃ₓ (0≤x≥1), for example, in a nanocrystalline form.

In some embodiments, the LSC can have one or more cladding layers in optical communication with an outer layer of waveguide materials of the LSC. The cladding layer can have a refractive index less than a refractive index of the waveguide materials, such that the cladding layer causes light to be confined within the waveguide materials by total internal reflection. In some embodiments, the LSC can further include a mirror separated from the bottom layer (relative to incident light) of the LSC either an air gap or a low-index layer. Direct contact with a bottom waveguide layer would likely diminish the total internal reflection efficiency of the waveguiding. In some embodiments, the mirror is not coupled to a light-utilization device.

In some embodiments, the LSC can further include an encapsulation layer on top of the layer including the quantum-cutting material, which can serve to protect the LSC from environmental conditions, such as moisture, oxygen, and other damaging effects. The encapsulation layer may also be an anti-reflection layer that is configured to allow maximum light impinging on the LSC into the luminophores contained within. In some embodiments, the encapsulation layer is not coupled to a light-utilization device.

In certain embodiments, the LSC includes oriented luminophores. For example, the luminophore layer with the longest emission wavelength can include oriented luminophores.

Fabrication of multilayer LSCs is accomplished using methods known to those of skill in the art and disclosed herein. For example, layers including photoluminescent nanoparticles can be fabricated using known methods (e.g., spin coating, drop coating, evaporation, vapor deposition, and the like). Layers including oriented luminophore layers can be fabricated using liquid crystals, extrusion, or other methods disclosed in U.S. Patent Application Publication No. 2011/0253198, filed Mar. 4, 2011, herein incorporated by reference in its entirety.

While LSC devices having layers that each includes a single photo-cutting material or broadly light-absorbing material are described, it will be appreciated that the layers can independently include multiple photo-cutting materials or broadly light-absorbing materials.

LSC Properties

An LSC that includes the quantum-cutting material and the broadly light-absorbing material can have an optical transmittance of 90% or more (95% or more, or 97% or more) below the bandgap energy of the quantum-cutting material and/or the broadly light-absorbing material. Depending on an application for the LSC, different combinations of transparency ranges and emission ranges can apply. For example, if the quantum-cutting material and the broadly light-absorbing material are to be used in a fully transparent window, the LSC that includes the quantum-cutting material and the broadly light-absorbing material can have a 90% or greater optical transmittance between 400 nm and 800 nm. If the quantum-cutting material and the broadly light-absorbing material are to be used in a partially transparent window, the LSC that includes the quantum-cutting material and the broadly light-absorbing material can have a 10% or greater (e.g., 25% or greater, 50% or greater, or 75% or greater) optical transmittance between 400 nm and 800 nm. If the quantum-cutting material and the broadly light-absorbing material are to be used for non-window applications, the LSC that includes the quantum-cutting material and the broadly light-absorbing material can exhibit less than 10% optical transmittance at energies higher than the bandgap.

In some embodiments, the LSC that includes the quantum-cutting material and the broadly light-absorbing material has an optical transmittance of 10% or less at energies greater than the bandgap energy of the quantum-cutting material and the broadly light-absorbing material. Such an LSC can be used for applications where it is more preferable to maximally absorb solar irradiance than to provide partial transparency at energies greater than the bandgap. For example, an LSC applied to a rooftop can provide greater benefit from maximally absorbing solar irradiance than by providing partial transparency. In another example, an LSC having transmittance of 10% or less at energies greater than the bandgap energy of the quantum-cutting material and the broadly light-absorbing material can be used to filter UV solar photons, and/or to harvest the maximum amount of solar energy.

The quantum-cutting material and the broadly light-absorbing material are well-suited for incorporation into a waveguide matrix for LSC applications. For example, the quantum-cutting material and the broadly light-absorbing material luminesce with high PLQYs and little to no self-absorption, which allows very large high-efficiency LSCs to be made. This can be important to reducing the cost of solar electricity generated using an LSC.

Another advantage of the quantum-cutting material and the broadly light-absorbing material of the present disclosure is that the range of wavelengths (color) of light absorbed by the quantum-cutting material and the broadly light-absorbing material can be tuned from the ultraviolet to the near-infrared by controlling their structure and chemical composition. This enables favorable matching to the solar spectrum, thereby increasing or optimizing the fraction of sunlight that can be harvested. As an example, an LSC incorporating the quantum-cutting material and the broadly light-absorbing material that selectively absorb only UV or infrared light would be optically transparent, but could still be used to generate electricity. Hence, LSCs of the present disclosure would be suitable for use as a window coating or a versatile architectural material for building exteriors, roofing, etc. Yet another advantage of the quantum-cutting material and the broadly light-absorbing material, in the case of inorganic materials, is that they can be more photochemically stable than most organic luminophores. This is important for producing a device that can function outdoors for many years, as required for most applications.

Yet a further advantage of the photoluminescent nanoparticles is that the quantum-cutting material and the broadly light-absorbing material can be processable in a number of solvents and by a number of methods, allowing facile integration into plastic or glass waveguide matrices at high concentration, and allowing co-deposition with the matrix material by scalable solution-based methods including spray coating, ultrasonic spray coating, spin coating, dip coating, infusion, roll-to-roll processing, and ink jet printing.

Quantum-Cutting Layer

In some embodiments, the quantum-cutting material has an absorption onset energy that is at least two times the emission energy of the quantum-cutting material. For example, the energy from the light absorbed by the quantum-cutting material can be emitted with a photoluminescence quantum efficiency of more than 100% (e.g., 120% or more, 140% or more, 160% or more, or 180% or more) and/or 200% or less (e.g., 180% or less, 160% or less, 140% or less, or 120% or less).

The quantum-cutting material is configured to absorb quanta of energy, such as photons. In some embodiments, the quantum-cutting material is configured to absorb light having wavelengths in a range of 250 nm or more (e.g., 300 nm or more, 400 nm or more, or 500 nm or more) and/or 600 nm or less (e.g., 500 nm or less, 400 nm or less, or 300 nm or less).

The quantum-cutting material can emit light at a wavelength of 800 nm or more (e.g., 900 nm or more, 1000 nm or more, or 1100 nm or more) and 1200 nm or less (e.g., 11 nm or less, 100 nm or less, or 900 nm or less).

In some embodiments, the quantum-cutting material includes a composition of formula Yb³⁺:CsPb(Cl₁₋ₓBrₓ)₃, wherein x is greater than or equal to 0 and less than or equal to 0.9.

In some embodiments, the quantum-cutting material has a chemical formula selected from the group of formulae consisting of:

M:ABX₃,

M:AB₂X₅, M:A₄BX₆,

M:C₂DX₅,

M:A₂CDX₆, and

combinations thereof,

wherein:

A is a cation selected from Li⁺, Na⁺, K⁺, Rb⁺, Cs⁺, methylammonium (MA), formamidinium (FA), guanidinium, dimethylammonium, trimethylammonium, and combinations thereof,

B is a cation selected from Pb²⁺, Sn²⁺, Ge²⁺, Cd²⁺, Mg²⁺, Ti²⁺, Hg²⁺ and combinations thereof,

C is a cation selected from Ag⁺, Cu⁺, Sn⁺, Na⁺, K⁺, Tl⁺, Au⁺, and combinations thereof,

D is a cation selected from the group consisting of In³⁺, Bi³⁺, Sb³⁺, Au³⁺, and combinations thereof,

X is an anion selected from O⁻, F⁻, Cl⁻, Br⁻, I⁻, CN⁻, and combinations thereof, and

M is a cation selected from Y³⁺, La³⁺, Ce³⁺, Pr³⁺, Nd³⁺, Pm³⁺, Sm³⁺, Eu³⁺, Gd³⁺, Tb³⁺, D³⁺, Ho³⁺, Er³⁺, Tm³⁺, Yb³⁺, Lu³⁺, Sc³⁺, Fe³⁺, Al³⁺, V²⁺, Cr²⁺, Mn²⁺, Bi³⁺, and combinations thereof.

The quantum-cutting material is configured to absorb a first quantum of energy having a first energy and configured to emit a second quantum of energy in response to absorbing the first quantum of energy, wherein the second quantum of energy is less than the first quantum of energy.

Without wishing to be bound by theory, it is believed that it is the sensitization of ytterbium ions (Yb³⁺) by broadband-absorbing semiconductors, such as metal-halide perovskites and elpasolites, that enable quantum-cutting.

In some embodiments, the quantum-cutting material is in the form of a film disposed on a substrate, such as a waveguide material. The films can be deposited from solutions of ionic precursors at low temperatures by methods that are compatible with existing large-area surface-coating technologies. The resulting films can show highly efficient quantum-cutting.

In some embodiments, the quantum-cutting material is in the form of particles, such as nanocrystals. The quantum-cutting material (e.g., in the form of particles) can be suspended in a waveguiding material. In certain embodiments, the quantum-cutting material is in the form of a film (e.g., a thin film, a continuous film, or a continuous thin film), which can have a thickness of 10 nm or more (e.g., 20 nm or more, 50 nm or more, 100 nm or more, 500 nm or more, 1 μm or more, 2 μm or more, 3 μm or more, or 4 μm or more) and/or 5 μm or less (e.g., 4 μm or less, 3 μm or less, 2 μm or less, 1 μm or less, 500 nm or less, 100 nm or less, 50 μm or less). In some embodiments, the quantum-cutting material in the form of a continuous film can have a thickness of 2000 nm or less (e.g., 2000 nm or less). In some embodiments, the quantum-cutting material is in the form of a continuous film having a thickness of 20 nm or more and 2000 nm or less. In an embodiment, the composition is in a bulk form having a largest dimension in a range of 1 μm or more (e.g., 100 μm or more, 1 cm or more, 5 cm or more, 8 cm or more) and/or to 10 cm or less (e.g., 8 cm or less, 5 cm or less, 1 cm or less, or 100 μm or less). The quantum-cutting material (e.g., in the form of particles or a continuous film) can be incorporated into and/or deposited onto a waveguiding material and is optically coupled to the waveguiding material.

As above, the quantum-cutting material can include a dopant, M. In an embodiment, M substitutes for B or D in a crystalline lattice. In an embodiment, a molar ratio of M/(B+M) is in a range of about 0% to about 49% (e.g., about 0% to about 20%). In an embodiment, a molar ratio of M/(D+M) is in a range of about 0% to about 49% (e.g., about 0% to about 20%).

Dopants, M, may or may not be associated with a defect of the crystalline lattice. In an embodiment, inclusion of M in the crystalline lattice is not associated with a cluster of M cations in the crystalline lattice. In an embodiment, inclusion of M in the crystalline lattice is associated with a cluster of two or more M cations. M can be homogeneously or inhomogeneously distributed within the quantum-cutting materials of the present disclosure. Accordingly, in an embodiment, the composition comprises a plurality of M cations, and the M cations of the plurality of M cations are inhomogeneously distributed within the composition. For example, redistributing a dopant distribution, such as a Yb³⁺ distribution, for quantum-cutting by changing the local ratio of excitons to Yb³⁺ dopants, can be important for solar irradiance-dependent effects. Correspondingly, in an embodiment, the quantum-cutting material comprises a plurality of M cations, and wherein M cations of the plurality of M cations are homogeneously distributed within the composition.

In an embodiment, the quantum-cutting material is suspended in a waveguiding matrix. In an embodiment, the quantum-cutting material is suspended in the matrix defines a spatial concentration gradient within the matrix. In an embodiment, the matrix, such as a polymer or glass, provides structural rigidity and improves the durability of the quantum-cutting material. Such a concentration gradient can be suitable to produce beneficial photonic effects by slowly grading the refractive index to reduce reflections of photons absorbed by the quantum-cutting material and increase reflection of photons emitted by the quantum-cutting material.

The number of emitted photons can be greater than a number of absorbed photons, such as when M is Yb³⁺. In an embodiment, the composition is selected from Yb³⁺:CsPbCl₃, Yb³⁺:CsPb(Cl₁₋ₓBrₓ)₃, Yb³⁺:CsSnCl₃, Yb³⁺:CsSn(Cl₁₋ₓBrₓ)₃, Yb³⁺:RbPbCl₃, Yb³⁺:RbPb(Cl₁₋ₓBrₓ)₃, Yb³⁺:(Rb₁₋ₓCsₓ)Pb(Cl₁₋ₓBrₓ)₃, Yb³⁺:FAPbCl₃, Yb³⁺:FAPb(Cl₁₋ₓBrₓ)₃, Yb³⁺:(FA₁₋ₓCsₓ)PbCl₃, Yb³⁺:(FA₁₋ₓCsₓ)Pb(Cl₁₋ₓBrₓ)₃, Yb³⁺:(Rb₁₋ₓCsₓ)(Pb₁₋ₓSnₓ)(Cl₁₋ₓBrₓ)₃, Yb³⁺:Cs₂PbCl₂I₂, Yb³⁺:Cs₂SnCl₂I₂, Yb³⁺:Cs₂AgBiCl₆, Yb³⁺:Cs₂AgBiBr₆, Yb³⁺:Cs₂AgBi(Cl₁₋ₓBrₓ)₆, Yb³⁺:Cs₂AgInCl₆, Yb³⁺:Cs₂AgIn(Cl₁₋ₓBrₓ)₆, Mn²⁺:CsPbCl₃, and Mn²⁺:CsPb(Cl₁₋ₓBrₓ)₃, wherein x is a number between 0 and 1.

The quantum-cutting material can be made using a precursor mixture. In an embodiment, the material precursor mixture includes one or more precursor materials selected from

M:ABX₃, M:AB₂X₅, M:A₄BX₆, M:C₂DX₅, M:A₂CDX₆, ABX₃, AB₂X₅, A₄BX₆, C₂DX₅, A₂CDX₆, AX, BX₂, CX, DX₃, MX₂, and MX₃,

wherein:

A is a cation selected from Li⁺, Na⁺, K⁺, Rb⁺, Cs⁺, methylammonium, formamidinium, guanidinium, dimethylammonium, trimethylammonium, and combinations thereof,

B is a cation selected from Pb₂+, Sn²⁺, Ge²⁺, Cd²⁺,Mg²⁺, Ti²⁺, Hg²⁺, and combinations thereof,

C is a cation selected from Ag⁺, Cu⁺, Sn⁺, Na⁺, K⁺, Tl⁺, Au⁺, and combinations thereof,

D is a cation selected from In³⁺, Bi³⁺, Sb³⁺, Au³⁺, and combinations thereof,

X is an anion selected from O⁻, F⁻, Cl⁻, Br⁻, I⁻, CN⁻, and combinations thereof, and

M is a cation selected from Y³⁺, La³⁺, Ce³⁺, Pr³⁺, Nd³⁺, Pm³⁺, Sm³⁺, Eu³⁺, Gd³⁺, Tb³⁺, D³⁺, Ho³⁺, Er³⁺, Tm³⁺, Yb³⁺, Lu³⁺, Sc³⁺, Fe³⁺, Al³⁺, V²⁺, Cr²⁺, Mn²⁺, Bi³⁺, and combinations thereof.

As discussed further herein, such a material precursor mixture can be used in the preparation of the quantum-cutting material. In an embodiment, the material precursor mixture is configured to form a composition having a chemical formula selected from:

M:ABX₃,

M:AB₂X₅,

M:A₄BX₆,

M:C₂DX₅,

M:A₂CDX₆, and

combinations thereof.

In an embodiment, a molar ratio of M/(B+M) of the composition is in a range of about 0% to about 49%. In an embodiment, a molar ratio of M/(D+M) of the composition is in a range of about 0% to about 49%.

In an embodiment, the quantum-cutting material is formed from the material precursor mixture using one or more of the methods described in International Application No. PCT/US2019/029355, entitled “Metal-Halide Semiconductor Optical and Electronic Devices and Methods of Making the Same,” filed Apr. 26, 2019, incorporated herein by reference in its entirety. For example, the material precursor mixture can be used in a sputtering target assembly configured to provide the quantum-cutting material when sputtered.

In an embodiment, the material precursor mixture is in a form such as a pellet, a disk, a wafer, a regular polygon, and/or a rectangle. Such forms may depend, for example, on the nature of transformations and/or manipulations used to prepare quantum-cutting material from the material precursor mixture.

Examples of quantum-cutting materials and methods of making them are described, for example, in International Application No. PCT/US2019/029355, entitled “Metal-Halide Semiconductor Optical and Electronic Devices and Methods of Making the Same,” filed Apr. 26, 2019, incorporated herein by reference in its entirety.

Broadly Light-Absorbing Layer

In some embodiments, the layer including a broadly light-absorbing material further includes one or more additional layers, each including one or more broadly light-absorbing materials. The one or more additional layers each can have a red-shifted absorption onset compared to the absorption onset of the quantum-cutting material. In some embodiments, the LSC can further include one or more additional layers beneath the layer including the broadly light-absorbing material, each additional layer optically coupled to an adjacent preceding layer and including a different broadly light-absorbing material compared to the adjacent preceding layer (relative to the incident light). In some embodiments, when the LSC includes more than one layer of broadly light-absorbing material, the broadly light-absorbing material in each successive layer can have a red-shifted absorption compared to the absorption of the broadly light-absorbing material in the adjacent preceding layer, relative to the incident light.

Thus, the layers that include broadly light-absorbing materials can be arranged from “bluest” to “reddest”, relative to the incident light, although it will be appreciated these terms are not indicative of the actual color of absorption or emission of the layer, but only indicating that the “bluest” is the shortest wavelength of light (e.g., emitted light), and the “reddest” is the light having the longest emission wavelength. Configurations of waveguide materials in an LSC are described, for example, in U.S. Patent Application Publication No. 2011/0253198, filed Mar. 4, 2011, incorporated herein by reference in its entirety.

It is understood that the layers including the broadly light-absorbing materials need not only harvest light directly from the layers preceding them in the energy cascade, but can also absorb and luminesce based on light directly impinging on the luminophores at the absorption wavelength.

The layer(s) that include the broadly light-absorbing material can each independently absorb 20% or more (e.g., 30% or more, 40% or more, 50% or more, 60% or more, 70% or more, or 80% or more) of incident light having a wavelength of 400 nm or more (e.g., 600 nm or more, 700 nm or more, or 800 nm or more) and emit light such that 20% or more (e.g., 30% or more, 40% or more, 50% or more, 60% or more, 70% or more, or 80% or more) of the emitted light has an energy greater than the absorption onset of the light-utilization device. The energy from light absorbed by each broadly light-absorbing material is emitted with a photoluminescence quantum efficiency of 100% or less.

The broadly light-absorbing material can include luminescent nanocrystals, such as CuIn(Se₁₋ₓSₓ)₂ (0≤x≤1), CuInS₂, Cu⁺:CdSeₓTe₁₋ₓ (0≤x≤1), Cu⁺:PbSₓSe₁₋ₓ (0≤x≤1), Cu⁺:InP Yb³⁺:CdSeₓTe₁₋ₓ (0≤x≤1), Yb³⁺:PbSₓSe₁₋ₓ (0≤x≤1), Cu⁺:InP, CdSeₓTe₁₋ₓ/Cd_{y}Zn_{1-y}S_{z}Se_{1-z} (0≤x≤1, 0≤y≤1, and 0≤z≤1) core/shell nanocrystals, and/or InP/ZnO core/shell nanocrystals; PbSₓSe₁₋ₓ/Cd_{y}Zn_{1-y}S_{z}Se_{1-z} (0≤x≤1, 0≤y≤1, and 0≤z≤1) core/shell nanocrystals; and/or CdSe/CdS dot-in-rod structures; luminescent molecular dyes, such as perylene, rhodamine 6G, platinum tetraphenyltetrabenzoporphyrin (Pt(TPBP)), 4-(dicyanomethylene)-2-tert-butyl-6-(1,1,7,7-tetramethyljulolidin-4-yl-vinyl)-4H-pyran (DCJTB), and Lumogen F Red 305 (from BASF); derivatives thereof; and/or luminescent films of such materials. Examples of materials for luminescent solar concentrators are described, for example, in Bradshaw et al., Nanocrystals for Luminescent Solar Concentrators, Nano Letters, 2015, 15, 1315-1323, incorporated herein by reference in its entirety.

In some embodiments, the broadly light-absorbing material has a chemical formula selected from the group of formulae consisting of:

M:ABX₃,

M:AB₂X₅, M:A₄BX₆,

M:C₂DX₅,

M:A₂CDX₆, and

combinations thereof,

wherein:

A is a cation selected from Li⁺, Na⁺, K⁺, Rb⁺, Cs⁺, methylammonium (MA), formamidinium (FA), guanidinium, dimethylammonium, trimethylammonium, and combinations thereof,

B is a cation selected from Pb²⁺, Sn²⁺, Ge²⁺, Cd²⁺, Mg²⁺, Ti²⁺, Hg²⁺ and combinations thereof,

C is a cation selected from Ag⁺, Cu⁺, Sn⁺, Na⁺, K⁺, Tl⁺, Au⁺, and combinations thereof,

D is a cation selected from the group consisting of In³⁺, Bi³⁺, Sb³⁺, Au³⁺, and combinations thereof,

X is an anion selected from O⁻, F⁻, Cl⁻, Br⁻, I⁻ CN⁻, and combinations thereof, and

M is a cation selected from Y³⁺, La³⁺, Ce³⁺, Pr³⁺, Nd³⁺, Pm³⁺, Sm³⁺, Eu³⁺, Gd³⁺, Tb³⁺, Dy³⁺, Ho³⁺, Er³⁺, Tm³⁺, Yb³⁺, Lu³⁺, Sc³⁺, Fe³⁺, Al³⁺, V²⁺, Cr²⁺, Mn²⁺, Bi³⁺, and combinations thereof.

In some embodiments, the broadly light-absorbing material is in the form of a film disposed on a substrate, such as a waveguide material. The films can be deposited from solutions of ionic precursors at low temperatures by methods that are compatible with existing large-area surface-coating technologies.

In some embodiments, the broadly light-absorbing material is in the form of particles. The broadly light-absorbing material (e.g., in the form of particles) can be suspended in a waveguiding material. In certain embodiments, the broadly light-absorbing material is in the form of a film (e.g., a thin film, a continuous film, or a continuous thin film), which can have a thickness of 10 nm or more (e.g., 20 nm or more, 50 nm or more, 100 nm or more, 500 nm or more, 1 μm or more, 2 μm or more, 3 μm or more, or 4 μm or more) and/or 5 μm or less (e.g., 4 μm or less, 3 μm or less, 2 μm or less, 1 μm or less, 500 nm or less, 100 nm or less, 50 μm or less). In some embodiments, the broadly light-absorbing material in the form of a continuous film can have a thickness of 2000 nm or less (e.g., 2000 nm or less). In some embodiments, the broadly light-absorbing material is in the form of a continuous film having a thickness of 20 nm or more and 2000 nm or less. In an embodiment, the composition is in a bulk form having a largest dimension in a range of 1 μm or more (e.g., 100 μm or more, 1 cm or more, 5 cm or more, 8 cm or more) and/or to 10 cm or less (e.g., 8 cm or less, 5 cm or less, 1 cm or less, or 100 μm or less). The broadly light-absorbing material (e.g., in the form of particles or a continuous film) can be incorporated into and/or deposited onto a waveguiding material and is optically coupled to the waveguiding material.

When the LSC includes more than one layer of broadly light-absorbing material, the broadly light-absorbing material in each successive layer can independently be in the form of particles and/or a film, as discussed above.

### Relationship Between the Quantum-Cutting Material and the Broadly Light-Absorbing Material

In some embodiments, the emission wavelength range of the quantum-cutting material and the absorption wavelength range of the one or more broadly light-absorbing materials combined have an overlap characterized in that 50% or more (e.g., 60% or more, 70% or more, 80% or more, or 90% or more) and/or 100% or less (e.g., 90% or less, 80% or less, 70% or less, or 60% or less) of the light emitted by the quantum-cutting material is not absorbed by the broadly light-absorbing materials, over a distance of 10 cm or less (e.g., 8 cm or less, 6 cm or less, 4 cm or less, or 2 cm or less) and/or 1 cm or more (e.g., 2 cm or more, 4 cm or more, 6 cm or more, or 8 cm or more).

In some embodiments, the absorption wavelength range of the quantum-cutting material and the absorption wavelength range of the one or more broadly light-absorbing materials overlap at wavelengths shorter than the absorption onset of the quantum-cutting material.

### Methods of Synthesis

In some embodiments, the quantum-cutting materials and/or the broadly light-absorbing material can be prepared using a variety of methods, as described below.

Mechanochemical Synthesis

In an embodiment of the method, crystalline powders are obtained from solid ionic precursors by solid-state mechanochemical synthesis. In an embodiment, stoichiometric amounts of solid ionic chemical precursors are mechanically mixed together to form the desired quantum-cutting materials and/or the broadly light-absorbing material. In an embodiment, the solid-state mechanochemical synthesis provides a crystalline powder.

In an embodiment, the solid ionic chemical precursors include solid ionic chemical precursors selected from hydrated solid ionic chemical precursors, anhydrous solid ionic chemical precursors, and combinations thereof. In an embodiment, the solid ionic chemical precursors are metal halides, metal oxides, metal acetates, metal nitrates, metal phosphates, and/or metal acetylacetonates.

In an embodiment, mechanochemically mixing solid ionic precursors includes shaking, grinding, crushing, and/or sonicating. In an embodiment, mechanochemically mixing solid ionic precursors includes use of mixing devices such as a mortar and pestle, a rotary ball mill, planetary ball mill, bath sonicator, probe sonicator, and/or vortexer.

In an embodiment, solid-state mechanochemical synthesis includes grinding solid ionic precursors for a time in a range of about 5 minutes to about 5 days.

In an embodiment, solid ionic precursors are mixed together simultaneously. In an embodiment, solid ionic precursors are mixed together at different stages of the preparation process to alter the composition.

In an embodiment, obtained powders, such as crystalline powders, are heated at temperatures in a range of about 50° C. to about 1500° C. In an embodiment heating the obtained powders includes heating under ambient and/or inert conditions.

Precipitation

In an embodiment, crystalline powders are obtained by precipitation from solution. In an embodiment, solid ionic chemical precursors are partially or completely solubilized in a liquid. In an embodiment, a desired composition of matter is obtained by mixing solid ionic chemical precursors in an appropriate stoichiometric ratio. In an embodiment, a solubilizing/suspending liquid includes a liquid such as water, DMSO, DMF, acetonitrile, methyl acetate, and/or HX(aq) (X=Cl, Br, I). In an embodiment, all of the ionic precursors are solubilized or suspended in a common solvent system in a single vessel.

In an embodiment, the method includes crystal formation driven, at least in part, by lowering a temperature of a solution of the solubilized ionic precursors and/or slow precipitation at fixed temperature. Powders can be isolated from the solvent mixture by filtration. Filtered powders may be heated and dried at temperatures in a range of about 50° C. to about 1500° C. under ambient or inert conditions.

In an embodiment, component ionic precursors are solubilized or suspended in multiple solvent systems in different vessels. Crystal formation may be driven by mixing of the various solvents containing ionic precursors into a single vessel. As above, powders may be isolated from the solvent mixture by filtration. Filtered powders may be heated and dried at temperatures in a range of about 50° C. to about 1500° C. under ambient or inert conditions.

Pressing Crystalline Powders

The methods can further include pressing such crystalline powders to provide pellets such as polycrystalline pellets or single crystalline pellets.

In an embodiment, where crystalline powders prepared by precipitation from a solution, the crystalline powders are loaded into a dry pellet pressing die. The die cavity may or may not be evacuated under vacuum. Pressure is applied to the dry pellet pressing die. In an embodiment, pressure is applied for a time in a range of about 5 seconds to about 5 days. In an embodiment, the crystalline powder in the die is heated at a temperature in a range of about 30° C. to about 1500° C. In an embodiment, pressure applied to the dry pellet die is in a range of about 10 MPa to about 1000 MPa.

In an embodiment, pressed pellets are heated at a temperature in a range of about 50° C. to about 1500° C. In an embodiment, heating pressed pellets is under ambient and/or inert conditions.

Pressed pellets may have various shapes depending on die geometry. In an embodiment, pressed pellets have a horizontal dimension on the order of millimeters to several centimeters. In an embodiment, pressed pellets have thicknesses ranging from micrometers to centimeters.

Such solid ionic chemical precursors can be hydrated solid ionic precursors, anhydrous ionic precursors, or combinations thereof. In an embodiment, the solid ionic chemical precursors are metal halides, metal oxides, metal acetates, metal nitrates, metal phosphates, and/or metal acetylacetonates.

Single Crystals

Single crystals can be made from solid ionic precursors. In an embodiment, the method includes mixing stoichiometric amounts of solid ionic chemical precursors in an evacuated vessel, such as in a ratio suitable to form a composition as described herein. In an embodiment, the vessel containing ionic precursors is heated, such as by placing the vessel in an oven. In an embodiment, the heated vessel containing ionic precursors is slowly cooled.

The resulting single crystals may have various shapes depending on vessel geometry. In an embodiment, the resulting single crystals have horizontal dimensions on the order of millimeters to centimeters. In an embodiment, the resulting crystals have a thicknesses ranging from micrometers to centimeters.

Wet Mechanochemical Synthesis

Crystalline colloidal suspensions can be made by wet mechanochemical synthesis of powders or single crystals. In an embodiment, the method includes loading powders or single crystals of composition described herein into a reaction vessel. In an embodiment, the method further includes loading surfactants and/or ligands into the reaction vessel. In an embodiment, surfactants can include oleic acid, metal-oleates, oleylamine, tri-n-octlyphoshine, tri-n-octylphosphine oxide, metal alkyl-phosphonates, phosphonic acids, phosphinic acids, alkyl thiols, oleylammonium fluoride, oleylammonium chloride, oleylammonium bromide, oleylammonium iodide, 3-(N,N-dimethyloctadecylammonio)propane sulfonate, benzoic acid and derivatives thereof, fluoroacetic acid, difluoroacetic acid, trifluoroacetic acid, and/or methylsulfonic acid.

In an embodiment, the method includes adding a solvent into the reaction vessel. In an embodiment, solvents can include hexane, octane, benzene, toluene, xylene, mesitylene, 1-octadecene, ethanol, methanol, isopropyl alcohol, acetone, DMSO, DMF, gamma-butyrolactone, N-methylformamide, propylene carbonate, glycol sulfite, formamide, acetonitrile, methyl acetate, HX(aq) (X=Cl, Br, I), and/or formic acid.

In an embodiment, mixing the contents of the reaction vessel includes mechanochemically mixing the reaction vessel contents by shaking, grinding, crushing, and/or sonicating the reaction vessel contents. In an embodiment, mechanochemically mixing includes use of instruments such as a mortar and pestle, rotary ball mill, planetary ball mill, bath sonicator, probe sonicator, and/or vortexer. In an embodiment, mechanochemically mixing the contents of the reaction vessel includes mechanochemically mixing the contents of the reaction vessel for a time in a range of about 5 minutes to about 5 days. In an embodiment, a temperature of the reaction vessel is in a range of about 30° C. to about 1500° C.

In an embodiment, contents of the reaction vessel are added together simultaneously. In an embodiment, contents of the reaction vessel are mixed together at different stages of the preparation process to alter the composition.

In an embodiment, reaction conditions are controlled such that resulting colloidal particles may have dimensions ranging from nanometers to micrometers. For example, variable reaction conditions to control resulting particle diameter include grinding duration, rotation speed, and precursor “ball-to-mass” ratio.

In an embodiment, obtained colloidal suspensions are purified, such as through cycles of centrifugation, re-dispersion in a suitable solvent, and/or flocculation using a suitable anti-solvent. In an embodiment, obtained colloidal suspensions are heated at temperatures in a range of about 50° C. to about 1500° C. Such heating can be performed under ambient conditions and/or inert conditions.

In an embodiment, obtained colloidal suspensions are diluted with the addition of solvent to control the final concentration of the crystalline colloidal suspension. In an embodiment, obtained colloidal suspensions are concentrated through the removal of solvent to form solids or powders.

Microwave Irradiation

Microwave irradiation of solutions of ionic precursors can provide crystalline colloidal suspensions of the quantum-cutting materials and/or the broadly light-absorbing material. In an embodiment, stoichiometric amounts of solid ionic chemical precursors are loaded into a reaction vessel and exposed to microwave radiation therein to form the quantum-cutting materials and/or the broadly light-absorbing material.

In an embodiment, contents of the reaction vessel are added together simultaneously. In an embodiment, contents of the reaction vessel are mixed together at different stages of the preparation process to alter the composition.

In an embodiment, the contents of the reaction vessel are microwaved for a time in a range of about 5 seconds to about 5 days. In an embodiment, a temperature of the reaction vessel is in a range of about 30° C. to about 1500° C.

In an embodiment, solid ionic chemical precursors can include hydrated solid ionic chemical precursors, and/or anhydrous solid ionic chemical precursors. In an embodiment, the solid ionic chemical precursors are metal halides, metal oxides, metal acetates, metal nitrates, metal phosphates, and/or metal acetylacetonates.

In an embodiment, the method further includes loading surfactants and/or ligands into the reaction vessel. In an embodiment, surfactants include oleic acid, metal-oleates, oleylamine, tri-n-octlyphoshine, tri-n-octylphosphine oxide, metal alkyl-phosphonates, phosphonic acids, phosphinic acids, alkyl thiols, oleylammonium fluoride, oleylammonium chloride, oleylammonium bromide, oleylammonium iodide, 3-(N,N-dimethyloctadecylammonio)propane sulfonate, benzoic acid and derivatives thereof, fluoroacetic acid, difluoroacetic acid, trifluoroacetic acid, and/or methylsulfonic acid.

In an embodiment, the method includes adding a solvent into the reaction vessel. In an embodiment, the solvents can include hexane, octane, benzene, toluene, xylene, mesitylene, 1-octadecene, ethanol, methanol, isopropyl alcohol, acetone, DMSO, DMF, gamma-butyrolactone, N-methylformamide, propylene carbonate, glycol sulfite, formamide, acetonitrile, methyl acetate, HX(aq) (X=Cl, Br, I), and/or formic acid.

In an embodiment, reaction conditions are controlled such that resulting colloidal particles may have dimensions ranging from nanometers to micrometers.

In an embodiment, obtained colloidal suspensions are purified through cycles of centrifugation, re-dispersion in a suitable solvent, and/or flocculation using a suitable anti-solvent. In an embodiment, obtained colloidal suspensions are heated at temperatures in a range of about 50° C. to about 1500° C., such as under ambient or inert conditions.

In an embodiment, obtained colloidal suspensions are diluted with the addition of solvent to control the final concentration of the crystalline colloidal suspension. In an embodiment, obtained colloidal suspensions are concentrated through the removal of solvent to provide solids or powders.

Sonication

Sonicating a solution and/or suspension of ionic precursors can be used to provide a crystalline colloidal suspension of the quantum-cutting materials and/or the broadly light-absorbing material.

In an embodiment, stoichiometric amounts of solid ionic chemical precursors are loaded into a reaction vessel to provide the quantum-cutting materials and/or the broadly light-absorbing material. In an embodiment, the solid ionic chemical precursors are hydrated solid ionic chemical precursors, and/or anhydrous solid ionic chemical precursors. In an embodiment, the solid ionic chemical precursors include solid ionic chemical precursors such as metal halides, metal oxides, metal acetates, metal nitrates, metal phosphates, and/or metal acetylacetonates.

In an embodiment, the method includes loading surfactants and/or ligands into to the reaction vessel. In an embodiment, the surfactants includes oleic acid, metal-oleates, oleylamine, tri-n-octlyphoshine, tri-n-octylphosphine oxide, metal alkyl-phosphonates, phosphonic acids, phosphinic acids, alkyl thiols, oleylammonium fluoride, oleylammonium chloride, oleylammonium bromide, oleylammonium iodide, 3-(N,N-dimethyloctadecylammonio)propane sulfonate, benzoic acid and derivatives thereof, fluoroacetic acid, difluoroacetic acid, trifluoroacetic acid, and/or methylsulfonic acid.

In an embodiment, the method includes loading a solvent into the reaction vessel. In an embodiment, the solvent is hexane, octane, benzene, toluene, xylene, mesitylene, 1-octadecene, ethanol, methanol, isopropyl alcohol, acetone, DMSO, DMF, gamma-butyrolactone, N-methylformamide, propylene carbonate, glycol sulfite, formamide, acetonitrile, methyl acetate, HX(aq) (X=Cl, Br, I), and/or formic acid.

In an embodiment, contents of the reaction vessel are sonicated for a time in a range of about 5 seconds to about 5 days. In an embodiment, a temperature of the reaction vessel is in a range of about 30° C. to about 1500° C.

In an embodiment, contents of the reaction vessel are added together simultaneously. In an embodiment, contents of the reaction vessel are mixed together at different stages of the preparation process to alter the composition.

In an embodiment, reaction conditions are controlled such that resulting colloidal particles may have dimensions ranging from nanometers to micrometers.

In an embodiment, obtained colloidal suspensions are purified through cycles of centrifugation, re-dispersion in a suitable solvent, and/or flocculation using a suitable anti-solvent. In an embodiment, obtained colloidal suspensions are heated at a temperature in a range of about 50° C. to about 1500° C., such as under ambient or inert conditions.

In an embodiment, obtained colloidal suspensions are diluted with the addition of solvent to control the final concentration of the crystalline colloidal suspension. In an embodiment, obtained colloidal suspensions are concentrated through the removal of solvent to provide solids or powders.

Co-Precipitation

Co-precipitation of solutions of ionic precursors to provide crystalline colloidal suspensions can be used to provide the quantum-cutting materials and/or the broadly light-absorbing material. In an embodiment, the method includes loading stoichiometric amounts of solid ionic chemical precursors two or more separate vessels to provide the quantum-cutting materials and/or the broadly light-absorbing material. In an embodiment, the component ionic precursors are solubilized or suspended in multiple solvent systems in different vessels.

In an embodiment, the solid ionic chemical precursors include hydrated solid ionic chemical precursors, and/or anhydrous solid ionic chemical precursors. In an embodiment, the solid ionic chemical precursors include metal halides, metal oxides, metal acetates, metal nitrates, metal phosphates, and/or metal acetylacetonates.

In an embodiment, the method includes loading surfactants and/or ligands to one or more of the reaction vessels. In an embodiment, the surfactants include oleic acid, metal-oleates, oleylamine, tri-n-octlyphoshine, tri-n-octylphosphine oxide, metal alkyl-phosphonates, phosphonic acids, phosphinic acids, alkyl thiols, oleylammonium fluoride, oleylammonium chloride, oleylammonium bromide, oleylammonium iodide, 3-(N,N-dimethyloctadecylammonio)propane sulfonate, benzoic acid and derivatives thereof, fluoroacetic acid, difluoroacetic acid, trifluoroacetic acid, and/or methylsulfonic acid.

In an embodiment, the method includes loading a solvent into one or more of the reaction vessels. In an embodiment, the solvent(s) include hexane, octane, benzene, toluene, xylene, mesitylene, 1-octadecene, ethanol, methanol, isopropyl alcohol, acetone, DMSO, DMF, gamma-butyrolactone, N-methylformamide, propylene carbonate, glycol sulfite, formamide, acetonitrile, methyl acetate, HX(aq) (X=Cl, Br, I), and/or formic acid.

In an embodiment, a temperature of the reaction vessels is/are in a range of about 30° C. to about 1500° C.

In an embodiment, the method includes rapid mixing of the two or more precursor solutions/suspensions to drive crystal formation. In an embodiment, the contents of the reaction vessels are added together simultaneously. In an embodiment, the contents of the reaction vessels are mixed together at different stages of the preparation process to alter the composition.

In an embodiment, reaction conditions are controlled such that resulting colloidal particles have dimensions ranging from nanometers to micrometers. For example, size control can be accomplished by varying the precursor-to-surfactant ratio, reaction temperature, and reaction duration.

In an embodiment, obtained colloidal suspensions are purified through cycles of centrifugation, re-dispersion in a suitable solvent, and/or flocculation using a suitable anti-solvent.

In an embodiment, obtained colloidal suspensions are heated at a temperature in a range of about 50° C. to about 1500° C., such as under ambient or inert conditions.

In an embodiment, obtained colloidal suspensions are diluted with the addition of solvent to control the final concentration of the crystalline colloidal suspension. In an embodiment, obtained colloidal suspensions are concentrated through the removal of solvent to provide solids or powders.

Post-Synthetic Chemical Treatment

The quantum-cutting materials and/or the broadly light-absorbing material can be modified through post-synthetic chemical treatment. In an embodiment, post-synthetic chemical treatment includes exposing compositions described herein to chemical species in solid, liquid, and/or gas phase(s).

In an embodiment, compositions are treated with chemical species to alter or introduce X anion composition such as AX, BX₂, CX, DX₃, X₂, MX₃, MX₂, oleylammonium-X, trimethylsilyl-X, benzoyl-X, or combinations thereof, wherein, A is a cation selected from Li⁺, Na⁺, K⁺, Rb⁺, Cs⁺, methylammonium, formamidinium, guanidinium, dimethylammonium, trimethylammonium, and combinations thereof, B is a cation selected from Pb²⁺, Sn²⁺, Ge²⁺, Cd²⁺, Mg²⁺, Ti²⁺, Hg²⁺, and combinations thereof, C is a cation selected from Ag⁺, Cu⁺, Sn⁺, Na⁺, K⁺, Tl⁺, Au⁺, and combinations thereof, D is a cation selected from In³⁺, Bi³⁺, Sb³⁺, Au³⁺, and combinations thereof, X is an anion selected from O⁻, F⁻, Cl⁻, Br⁻, I⁻, CN⁻, and combinations thereof, and M is a cation selected from Y³⁺, La³⁺, Ce³⁺, Pr³⁺, Nd³⁺, Pm³⁺, Sm³⁺, Eu³⁺, Gd³⁺, Tb³⁺, Dy³⁺, Ho³⁺, Er³⁺, Tm³⁺, Yb³⁺, Lu³⁺, Sc³⁺, Fe³⁺, Al³⁺, V²⁺, Cr²⁺, Mn²⁺, Bi³⁺, and combinations thereof.

In an embodiment, compositions are treated with chemical species to alter or introduce A cation into a composition, such as metal halides, metal oxides, metal acetates, metal nitrates, metal phosphates, and/or metal acetylacetonates, where the metal is composed of A cations. In an embodiment, A is a cation selected from Li⁺, Na⁺, K⁺, Rb⁺, Cs⁺, methylammonium, formamidinium, guanidinium, dimethylammonium, trimethylammonium, and combinations thereof.

In an embodiment, compositions are treated with chemical species to alter or introduce B cation into the quantum-cutting materials and/or the broadly light-absorbing material. The chemical species can be selected from metal halides, metal oxides, metal acetates, metal nitrates, metal phosphates, metal acetylacetonates, and combinations thereof, where the metal is composed of B cations. In an embodiment, B is a cation selected from Pb²⁺, Sn²⁺, Ge²⁺, Cd²⁺, Mg²⁺, Ti²⁺, Hg²⁺, and combinations thereof.

In an embodiment, compositions are treated with chemical species to alter or introduce C cation into a composition selected from metal halides, metal oxides, metal acetates, metal nitrates, metal phosphates, metal acetylacetonates, and combinations thereof, where the metal is composed of C cations. In an embodiment, C is a cation selected from Ag⁺, Cu⁺, Sn⁺, Na⁺, K⁺, Tl⁺, Au⁺, and combinations thereof.

In an embodiment, compositions are treated with chemical species to alter or introduce D cation into a composition selected from metal halides, metal oxides, metal acetates, metal nitrates, metal phosphates, metal acetylacetonates, and combinations thereof, where the metal is composed of D cations. In an embodiment, D is a cation selected from In³⁺, Bi³⁺, Sb³⁺, Au³⁺, and combinations thereof.

In an embodiment, compositions are treated with chemical species to alter or introduce M cation into a composition selected from metal halides, metal oxides, metal acetates, metal nitrates, metal phosphates, metal acetylacetonates, and combinations thereof, where the metal is composed of M cations. In an embodiment, M is a cation selected from Y³⁺, La³⁺, Ce³⁺, Pr³⁺, Nd³⁺, Pm³⁺, Sm³⁺, Eu³⁺, Gd³⁺, Tb³⁺, Dy³⁺, Ho³⁺, Er³⁺, Tm³⁺, Yb³⁺, Lu³⁺, Sc³⁺, Fe³⁺, Al³⁺, V²⁺, Cr²⁺, Mn²⁺, Bi³⁺, and combinations thereof.

In an embodiment, a surface chemistry of the crystals is altered by the introduction and/or replacement of surfactant/ligand molecules or inorganic matrices.

Deposition of Quantum-Cutting Material and/or Broadly Light-Absorbing Material

In another aspect, the present disclosure provides a method of depositing the quantum-cutting materials and/or the broadly light-absorbing material onto a substrate, such as a waveguide.

Crystalline Colloidal Suspension Deposition

In one embodiment, the method includes depositing a crystalline colloidal suspension as described herein onto the substrate. In an embodiment, depositing the crystalline colloidal suspension includes a deposition method selected from drop casting, dip coating, spin casting, slot-die printing, spray coating, screen printing, ink-jet printing, and combinations thereof onto a substrate.

In an embodiment, the resulting layer is heated at a temperature in a range of about 30° C. to 1000° C. In an embodiment, the resulting layer has a thickness in a range of about 5 nm to about 1000 nm.

Ionic Precursor Solution or Suspension Deposition

In an embodiment, the method includes deposition of solutions or suspensions of ionic precursors to provide a layer of the quantum-cutting materials and/or the broadly light-absorbing material. In an embodiment, deposition of solutions and/or suspensions of ionic precursors is performed in a single deposition step. In an embodiment, stoichiometric amounts of solid ionic chemical precursors are loaded into a vessel to form the desired composition of matter. In an embodiment, deposition of solutions or suspensions of ionic precursors the ionic precursors includes two or more deposition steps. In an embodiment, stoichiometric amounts of solid ionic chemical precursors are loaded into two or more separate vessels to provide the desired composition of matter.

In an embodiment, the solid ionic chemical precursors are selected from hydrated solid ionic chemical precursors, anhydrous solid ionic chemical precursors, and combinations thereof. In an embodiment, the solid ionic chemical precursors are selected from metal halides, metal oxides, metal acetates, metal nitrates, metal phosphates, metal acetylacetonates, and/or combinations thereof.

In an embodiment, additional molecules or reagents are added to the vessel(s) to restrict grain size and/or promote precursor solubility. In an embodiment, such additives are selected from oleic acid, metal-oleates, oleylamine, tri-n-octlyphoshine, tri-n-octylphosphine oxide, metal alkyl-phosphonates, phosphonic acids, phosphinic acids, alkyl thiols, oleylammonium fluoride, oleylammonium chloride, oleylammonium bromide, oleylammonium iodide, 3-(N,N-dimethyloctadecylammonio)propane sulfonate, benzoic acid and derivatives thereof, fluoroacetic acid, difluoroacetic acid, trifluoroacetic acid, methylsulfonic acid, and combinations thereof.

In an embodiment, a solvent is added into the vessel(s). In an embodiment, the solvent is selected from hexane, octane, benzene, toluene, xylene, mesitylene, 1-octadecene, ethanol, methanol, isopropyl alcohol, acetone, DMSO, DMF, gamma-butyrolactone, N-methylformamide, propylene carbonate, glycol sulfite, formamide, acetonitrile, methyl acetate, HX(aq) (X=Cl, Br, I), formic acid, and combinations thereof.

In an embodiment, the vessel(s) is/are heated and mixed to promote precursor dissolution to form a precursor ink. In an embodiment, the method includes deposition the precursor ink onto the substrate. In an embodiment, depositing the ionic precursor ink occurs in a single step. Such deposition can occur by a method selected from drop casting, dip coating, spin casting, slot-die printing, spray coating, screen printing, ink-jet printing, and combinations thereof onto the substrate.

In an embodiment, the resulting deposited material is heated at a temperature in a range of about 30° C. to about 1000° C. In an embodiment, the resulting deposited material is placed under vacuum at a pressure in a range of about 1×10¹⁶ atm to about 10×10¹⁶ atm.

In an embodiment, the solid ionic chemical precursors are selected from hydrated solid ionic chemical precursors, anhydrous solid ionic chemical precursors, and mixtures thereof. In an embodiment, the solid ionic chemical precursors are selected from metal halides, metal oxides, metal acetates, metal nitrates, metal phosphates, metal acetylacetonates, and combinations thereof.

Thermal Evaporation

The one or more precursors can be thermally evaporated. In an embodiment the precursors are selected from crystalline powders, solid ionic precursors, single crystals of the present disclosure, and combinations thereof. In an embodiment, thermal evaporation includes thermally evaporating the crystalline powders, solid ionic precursors, or single crystals of the present disclosure in a vacuum and/or in an inert atmosphere.

In an embodiment, the thermal evaporation methods described herein are performed in a thermal evaporation chamber. Precursor mixtures, such as mechanochemically synthesized metal-halide powders and/or colloids of metal-halide powders can be loaded into an evaporation boat, such as molybdenum or tantalum evaporation boat suspended between two electrodes or onto a tantalum foil suspended between two electrodes inside of a vacuum chamber. The source material is rapidly evaporated/sublimated upon contact with the heating element and the resulting vapor is deposited onto a substrate. A thermal heating element is held at a desired temperature inside of a deposition chamber. The heating element can be resistively heated or heated via irradiation from a remote source.

A substrate, such as a piece of glass, a solar cell, flexible sheet, etc., onto which the evaporated composition is to be deposited may be positioned above a heater at a distance suitable for such deposition. In an embodiment, such a distance is in a range of about 1 cm to about 50 cm. In an embodiment, the evaporation chamber is evacuated to a pressure in a range of about 1×10⁻³ mTorr to 1×10⁻⁴ mTorr. In an embodiment, a large electrical current is quickly passed through the electrodes, heating the evaporation boat/foil and vaporizing the precursor mixture. In this regard, the vaporized material is deposited onto the substrate suspended above the evaporation boat/foil.

In an embodiment of the method, layers of the metal-halide semiconductor material are obtained by continuous evaporation/sublimation of a source material onto a substrate. In an embodiment, the thermal evaporation methods include thermal evaporation in an evaporation chamber in which source materials are provided with a feeder or other structure configured to provide a continuous or semi-continuous source of source materials. As shown, the source material is supplied to the thermal heater via a powder feeder. In an embodiment, the source material is a mixture of ionic precursor powders or a single-source metal-halide powder. In an embodiment, deposition chamber is brought to vacuum or put under an inert or reactive gas atmosphere. Example implementations of a powder feeder include a vibratory feeder or powder suspended in a pressurized carrier gas. The rate of source material sublimation can be controlled by adjusting the powder feeder rate, including suspending material deposition. Likewise, film thickness and uniformity can be controlled by altering the distance between the heating element and substrate, or by setting the rate at which source powder is supplied to the thermal heater. The substrate can be held in a fixed position or translating. The substrate can be rotating. The substrate can be heated or cooled.

Substrates can be coated according to the methods described herein in a continuous or semicontinuous way. For example, a number of substrates can be moved past a vapor plume of thin film source materials in the deposition chamber on a rolling conveyor belt, and a number of substrates can be passed through the evaporation chamber and coated. Such an arrangement is suitable to dispose coatings on a number of substrates.

The evaporation boat can be heated through electrical resistive heating. For example, the evaporation boat can be heated with radiation source. It will be understood that other heating sources and methods are possible within the scope of the present disclosure.

In an embodiment, the method can include sequentially thermally evaporating precursors onto the substrate. In an embodiment, sequentially thermally evaporating the precursors includes thermally evaporating a precursor selected from crystalline powders, solid ionic precursors, single crystals described herein, and combinations thereof. In an embodiment, sequential thermal evaporation is performed in a vacuum. In an embodiment, sequential thermal evaporation is performed an inert atmosphere.

In an embodiment, thermal evaporation includes thermal evaporation of the one or more precursors at a pressure in a range of about 1 to about 1×10¹⁶ atm. In an embodiment, thermal evaporation includes thermal evaporation of the one or more precursors in an inert gas atmosphere

In an embodiment, thermal evaporation includes heating the one or more precursors to a temperature in a range of about 30° C. to about 1000° C. In an embodiment, thermal evaporation of the one or more precursors includes deposits the one or more precursors on the substrate at a rate in a range of about 0.01 Å/s to about 100 Å/s.

In an embodiment, the one or more precursors are evaporated at a stoichiometric rate to produce the composition of the present disclosure. In an embodiment, the composition varies through a thickness of the composition.

In an embodiment, the substrate is heated relative to a temperature of a thermal evaporation chamber. In an embodiment, the substrate is cooled relative to a temperature of the thermal evaporation chamber.

In an embodiment, the deposited layer is heated after thermal evaporation. In an embodiment, such heating is performed in conditions selected from a vacuum, inert atmosphere, or reactive atmosphere. In an embodiment, such heating is suitable to drive formation the composition of matter.

Sputtering

The method can include sputtering a target assembly of quantum-cutting material and/or broadly light-absorbing material to provide one or more layers of luminophores of the present disclosure. In an embodiment, the target assembly is a target assembly as described further herein.

In an embodiment, sputtering the target assembly deposits the quantum-cutting material and/or broadly light-absorbing material onto the substrate at a rate in a range of about 0.01 Å/s to about 500 Å/s. In an embodiment, the target is sputtered at a stoichiometric rate to produce the desired composition of matter. In an embodiment, the composition varies as a function of a thickness of the composition.

In an embodiment, the substrate is heated relative to a temperature of a sputtering chamber. In an embodiment, the substrate is cooled relative to a temperature of a sputtering chamber.

In an embodiment, sputtering occurs in vacuum, such as at a pressure in a range of about 1 atm to about 1×10¹⁶ atm. In an embodiment, sputtering occurs in an inert gas atmosphere.

In an embodiment, the resulting layer is heated after deposition. In an embodiment, such heating occurs under conditions selected from a vacuum, an inert atmosphere, and reactive atmosphere. In an embodiment, such heating is suitable to drive formation of the desired composition.

In an embodiment, sputtering the target assembly includes sequentially sputtering targets including precursor materials to provide the quantum-cutting material and/or broadly light-absorbing material. In an embodiment, an average stoichiometry of two or more successive layers produces the desired product. In an embodiment, the precursors are selected from metal halides, metal oxides, metal acetates, metal nitrates, metal phosphates, metal acetylacetonates, and combinations thereof. In an embodiment, a precursor film thickness is in a range of about 1 Å to about 500 Å. In an embodiment, the precursors are deposited at a rate in a range of about 0.01 Å/s to 500 Å/s. In an embodiment, the resulting layer is heated after deposition in a vacuum, inert atmosphere, or reactive atmosphere to drive formation of the desired composition of matter.

Chemical Vapor Deposition

In some embodiments, the method includes chemical vapor deposition (CVD) of one or more precursors to provide the quantum-cutting material and/or broadly light-absorbing material. In an embodiment, CVD includes plasma-enhanced chemical vapor deposition (PECVD).

In an embodiment, a concentration of precursors at the substrate is controlled to produce a stoichiometric ratio, corresponding to the desired composition of matter. In an embodiment, the desired composition of matter varies as a function of layer thickness.

In an embodiment, a substrate temperature is varied in a range of about 5 K to about 1000° C. In an embodiment, a chamber pressure is varied from 1 and 1×10¹⁶ atm.

In an embodiment, the one or more precursors include a Yb³⁺ CVD precursors. In an embodiment, the Yb³⁺ CVD precursor is selected from Tris[N,N-bis(trimethylsilyl)amide]ytterbium(III), Tris(cyclopentadienyl)ytterbium(III), Yb(acac)3, Tris(cyclopentadienyl)ytterbium, Tris(N,N′-di-i-propylacetamidinato)ytterbium(III), Tris(2,2,6,6-tetramethyl-3,5-heptanedionato)ytterbium(III), Ytterbium(III) hexafluoroacetylacetonate dihydrate, and combinations thereof.

In an embodiment, the resulting layer is heated after deposition. Such heating can include heating in conditions selected from a vacuum, inert atmosphere, or reactive atmosphere. In an embodiment, such heating is suitable to drive formation of the desired composition of matter.

Electron Beam Deposition

In an embodiment, the method includes electron beam deposition of one or more precursors to provide the quantum-cutting material and/or broadly light-absorbing material. In an embodiment, the one or more precursors are selected from crystalline powders, solid ionic precursors, single crystals described further herein, and combinations thereof. In an embodiment, electron beam deposition is conducted in a vacuum or inert atmosphere.

In an embodiment, the one or more precursors are deposited on a substrate at a rate in a range of about 0.01 Å/s to about 100 Å/s. In an embodiment, the one or more precursors are deposited at a stoichiometric rate suitable to provide the desired material. In an embodiment, the deposited composition varies as function of a thickness of the composition.

In an embodiment, the substrate is heated relative to an electron beam deposition chamber. In an embodiment, the substrate is cooled relative to an electron beam deposition chamber.

In an embodiment, the resulting quantum-cutting material and/or broadly light-absorbing material is heated after electron beam deposition. In an embodiment, such heating is under conditions selected from a vacuum, an inert atmosphere, and reactive atmosphere. In an embodiment, such heating is suitable to drive formation of the desired composition of matter. Heating can drive diffusion, reactions with a reactive atmosphere to oxidize, reduce, or otherwise chemically modify the film.

In embodiment, electron beam deposition includes sequential electron beam deposition of the one or more precursor materials. In an embodiment, an average stoichiometry of two or more successive layers provides the quantum-cutting material and/or broadly light-absorbing material.

In an embodiment, the one or more precursors are selected from metal halides, metal oxides, metal acetates, metal nitrates, metal phosphates, metal acetylacetonates, and combinations thereof.

Pulsed Laser Deposition

In some embodiments, the method includes pulsed laser deposition of one or more precursors to provide the quantum-cutting material and/or broadly light-absorbing material. In an embodiment, the one or more precursors are selected from crystalline powders, solid ionic precursors, single crystals of the present disclosure, and combinations thereof. In an embodiment, pulsed laser deposition is conducted in a vacuum or inert atmosphere.

In an embodiment, a local stoichiometric ratio of deposited materials produces the desired composition. In an embodiment, the deposited composition varies as a function of thickness of the composition.

In an embodiment, the substrate is heated relative to a pulsed laser deposition chamber. In an embodiment, the substrate is cooled relative to the pulsed laser deposition chamber.

In an embodiment, the resulting thin layer is heated after deposition. In an embodiment, such heating is conducted under conditions selected from a vacuum, an inert atmosphere, and reactive atmosphere. In an embodiment, such heating is suitable to drive formation of the desired composition of matter.

Methods of Forming a Precursor Mixture

In another aspect, the present disclosure provides a method of forming a precursor mixture. In an embodiment, the method includes mixing one or more precursor materials to form the precursor mixture. In an embodiment, the one or more precursor materials for the quantum-cutting material and/or the broadly light-absorbing material are selected from:

M:ABX₃, M:AB₂X₅, M:A₄BX₆, M:C₂DX₅, M:A₂CDX₆, ABX₃, AB₂X₅, A₄BX₆, C₂DX₅, A₂CDX₆, AX, BX₂, CX, DX₃, MX₂, and MX₃,

wherein

A is a cation selected from Li⁺, Na⁺, K⁺, Rb⁺, Cs⁺, methylammonium,

formamidinium, guanidinium, dimethylammonium, trimethylammonium, and combinations thereof,

B is a cation selected from Pb²⁺, Sn²⁺, Ge²⁺, Cd²⁺, Mg²⁺, Ti²⁺, Hg²⁺, and combinations thereof,

C is a cation selected from Ag⁺, Cu⁺, Sn⁺, Na⁺, K⁺, Tl⁺, Au⁺, and combinations thereof,

D is a cation selected from In³⁺, Bi³⁺, Sb³⁺, Au³⁺, and combinations thereof,

X is an anion selected from O⁻, F⁻, Cl⁻, Br⁻, I⁻, CN⁻, and combinations thereof, and

M is a cation selected from Y³⁺, La³⁺, Ce³⁺, Pr³⁺, Nd³⁺, Pm³⁺, Sm³⁺, Eu³⁺, Gd³⁺, Tb³⁺, D³⁺, Ho³⁺, Er³⁺, Tm³⁺, Yb³⁺, Lu³⁺, Sc³⁺, Fe³⁺, Al³⁺, V²⁺, Cr²⁺, Mn²⁺, Bi³⁺ and combinations thereof.

In an embodiment, the precursor mixture is suitable for use in making the quantum-cutting material.

In an embodiment, making a composition of the present disclosure using the precursor mixture is conducted according to one or more of the methods described further herein.

In an embodiment, forming one or more precursor materials includes pulverizing precursor materials to form a crystalline powder. In an embodiment, pulverization includes a form of pulverization selected from shaking, grinding, crushing, and sonicating. In an embodiment, pulverization includes use of an instrument selected from a mortar and pestle, rotary ball mill, planetary ball mill, bath sonicator, probe sonicator, vortexer, and combination thereof.

In an embodiment, the method includes sintering the crystalline powder. In an embodiment, sintering the crystalline power includes sintering the crystalline powder at a temperature in a range of about 100° C. to about 1500° C. In an embodiment, the crystalline powder is sintered for a time in a range of about 0.01 hours to about 48 hours. In an embodiment, the sintered powder is pulverized one or more times.

In an embodiment, the crystalline powder is sintered under vacuum at a pressure down to about 1×10⁻⁶ torr. In an embodiment, the crystalline powder is sintered in an inert atmosphere. In an embodiment, the crystalline powder is sintered under ambient conditions.

In an embodiment, the method includes pressing the crystalline powder into a pellet. In an embodiment the method includes sintering the pellet. In an embodiment, the crystalline powder is pressed into a mechanically stable shape. In an embodiment, the crystalline powder is pressed at a pressure in a range of about 10 MPa to about 1000 MPa. In an embodiment, the crystalline powder is pressed under a vacuum having a pressure as low as about 1×10⁻⁶ torr. In an embodiment, pressing occurs under an inert atmosphere.

In an embodiment, pressing the crystalline powder includes pressing with a press, such as a press selected from hydraulic, pneumatic, and mechanical presses. In an embodiment, the press uses a plate or die.

In an embodiment, a shape of the pressed crystalline powder is selected from a disk, a rectangle, and a polygon. In an embodiment, the pressed crystalline powder has a longest dimension of about 1 meter. In an embodiment, the pressed crystalline powder has a thickness of down to about 1 mm. In an embodiment, the pressed crystalline powder is further altered a die or mill.

In an embodiment, the precursor materials are selected from metal halides, metal oxides, metal acetates, metal nitrates, metal phosphates, metal acetylacetonates, and combinations thereof.

### Light-Utilization Device

As discussed above, the LSC of the present disclosure can be optically coupled to a light-utilization device (e.g., a photovoltaic cell). The light-utilization device is in optical communication with one or more surfaces (e.g., a minor surface, such as an edge) of one or more layers of the luminescent solar concentrator. In some embodiments, the light-utilization device is in optical communication with the edge of 2 or more layers (e.g., 3 or more, 4 or more, 5 or more, or 6 or more) and/or 7 or less (e.g., 6 or less, 5 or less, 4 or less, or 3 or less) of the LSC. The absorption onset of the coupled light-utilization device can be lower in energy than the emission maximum of the luminescent solar concentrator. For example, at least 50% (e.g., at least 60%, at least 70%, at least 80%, or at least 90%) and/or up to 100% (e.g., up to 90%, up to 80%, up to 70%, or up to 60%) of the emitted light of the LSC can be above the absorption onset of the light-utilization device.

The LSC can be made in a variety of colors, and can even be optically transparent, rendering the LSC useful as solar windows or other building-integrated architectural elements. The LSC can be configured for a variety of potential applications ranging from consumer electronics to utility-scale solar farm deployment. Because the materials and installation costs of an LSC are lower than those for conventional photovoltaic panels, solar electricity generated using an LSC has the potential to be significantly cheaper than other forms of solar power.

As an example, the LSC can be used for window applications. In some embodiments, the optical transmittance of the quantum-cutting material and/or the broadly light-absorbing material (and of the resulting LSC) can be tuned depending on the application. The LSC of the present disclosure can have a peak emission at wavelengths longer than 850 nm, so as to decrease visible “glow.” In some embodiments, for window and other applications, visible glow is alternatively or additionally reduced (or eliminated) by incorporating into a cladding layer an absorbing non-emissive species such as an organic dye, whose absorption range can overlap with the emission range of the quantum-cutting material and/or the broadly light-absorbing material. The dye-containing cladding layer can be separated from the waveguide layer by a low refractive index layer, thereby absorbing light leaving the waveguide layer out of its escape cone.

In some embodiments, for optimal interfacing of the LSC to silicon photovoltaics, a maximal emission wavelength is between 900-1100 nm. In general, optimal interfacing to a photovoltaic device is achieved when the emission maximum of the quantum-cutting material and/or the broadly light-absorbing material is slightly higher in energy than the bandgap of the photovoltaic.

The light-utilization device can be a photovoltaic cell, a solar heater, a concentrated solar thermal power system, a lighting device, or a photochemical reactor. In some embodiments, the light-utilization device is a photovoltaic cell.

In some embodiment, an article, such as a window pane, a coating, a free-standing polymer film, an electronic display, and/or a touch screen can include the LSC of the present disclosure.

In some embodiments, the LSC forms or is part of a coating for a device.

In some embodiments, the LSC forms or is part of a free-standing polymer film.

In some embodiments, the LSC forms part of an electronic display or a touch screen.

The following Examples are included for the purpose of illustrating, not limiting, the described embodiments.

### Examples

Quantum-Cutting Yb³⁺-Doped Perovskite Nanocrystals for Monolithic Bilayer Luminescent Solar Concentrators

A 120 cm 1D LSC was used to demonstrate that Yb³⁺:CsPbCl₃ NCs behave as zero-reabsorption, high-efficiency luminophores suitable for application in large-scale LSCs. Yb³⁺:CsPbCl₃ NCs was shown to have negligible intrinsic attenuation losses over these large waveguide lengths, but also that severe attenuation is still observed when the waveguide contains C—H bonds (high-frequency vibrations). A new monolithic-bilayer LSC device architecture integrating quantum-cutting is presented here, that offers an attractive alternative to traditional tandem LSCs. This new device concept is fundamentally different from tandem LSCs in that the concentrated photons from both luminophore layers are all directed via the same waveguide to the same PV, circumventing the expenses and technical challenges associated with current matching in normal tandem devices. The present example illustrates the integration of a layer of band-gap-optimized Yb³⁺:CsPb(Cl₁₋ₓBrₓ)₃ NCs on top of a state-of-the-art CuInS₂ NC LSC in a monolithic bilayer configuration and shows improvement of overall LSC performance by at least 19%. Thus, LSCs can capitalize on the unique spectroscopic and photophysical properties of quantum-cutting Yb³⁺:CsPb(Cl₁₋ₓBrₓ)₃ NCs.

Materials. Lead acetate trihydrate [Pb(OAc)₂.3H₂O] (99.9%, Baker Chemical), ytterbium acetate hydrate [Yb(OAc)₃.xH₂O] (99.9%, Strem Chemical), cesium acetate [CsOAc] (99.9%, Alfa Aesar), anhydrous ethanol (200 proof, Decon Laboratories, Inc.), chlorotrimethylsilane (TMS-Cl) (98%, Acros Organics), bromotrimethylsilane (TMS-Br) (97%, Sigma Aldrich), 1-octadecene (ODE) (90%, Sigma Aldrich), oleylamine (OAm) (70%, Sigma Aldrich), oleic acid (OA) (90%, Sigma Aldrich), hexanes (99%, Sigma Aldrich), tetrachloroethylene (TCE) (99%, Alfa Aesar), anhydrous ethyl acetate (99%, Sigma Aldrich), and ¼″ and ⅛″ extruded poly(methyl methacrylate) (PMMA) slabs (Evonik Cyro LLC) were used as received unless otherwise noted.

Nanocrystal synthesis and purification. Yb³⁺:CsPbCl₃ NCs with the highest Yb³⁺ emission quantum yield were synthesized by hot-injection following procedures described, for example, in T. J. Milstein, D. M. Kroupa and D. R. Gamelin, Nano Lett., 2018, 18, 3792 3799, incorporated herein by reference in its entirety. Samples suspended in TCE were not filtered after washing and purification. To synthesize the mixed Yb³⁺:CsPb(Cl₁₋ₓBrₓ)₃ NCs, a freshly synthesized Yb³⁺:CsPbCl₃ NC sample in hexane was transferred into an N₂ filled glovebox. Small amounts of 1 M TMS-Br in hexane were titrated into the NC sample until the absorption onset reached 488 nm.

Physical measurements. Optical absorption spectra in the visible regime that require a 1 cm cuvette were collected at room temperature using a Cary 60 spectrometer. All other optical absorption spectra were collected at room temperature using a Cary 5000 spectrometer. Wavelength independent absorption constants were added to the absorption spectra of hexanes and TCE to account for reflection losses. NC transmission electron microscopy (TEM) images were collected using a FEI TECNAI F20 microscope at 200 kV. TEM samples were prepared by drop casting NC suspensions onto carbon-coated copper grids from TED Pella, Inc. Powder X-ray diffraction (XRD) spectra were collected using a Bruker D8 Advance diffractometer. Samples were prepared by drop-casting NC suspensions onto monocrystalline silicon wafer substrates. Samples were irradiated using Cu Kα radiation (50 W). Photoluminescence spectra for photoluminescence quantum yield (PLQY) and 1D LSC experiments were collected using a monochromator coupled to a spectrally corrected nitrogen-cooled CCD. PLQY measurements were performed according to the procedures described in T. J. Milstein, D. M. Kroupa and D. R. Gamelin, Nano Lett., 2018, 18, 3792 3799, incorporated herein in its entirety. Elemental compositions were determined by inductively coupled plasma—atomic emission spectroscopy (ICP-AES, PerkinElmer 8300). Samples were prepared by digesting the NCs in concentrated nitric acid overnight with sonication. Yb³⁺ atomic concentrations are defined as [Yb³⁺]/([Yb³⁺]+[Pb²⁺])

1D LSC measurements. The apparatus for measuring LSC reabsorption losses used here is based on a 120 cm long hollow quartz waveguide (Friederick and Dimmock Co.) with a 1 mm×1 mm square inner dimension and 1.65 mm×1.65 mm outer dimension, suspended over a black aluminum channel. The quartz tube was filled with sample using a removable capillary tube. A 375 nm pulsed laser passed through an iris at its smallest setting was used as the excitation source. Emission from the 1D LSC is treated as a point source and was collected using our homebuilt CCD setup. The excitation source distance from the closed end of the tube was varied by moving the laser across the laser table and aligning the laser perpendicular to the tube to maximize signal.

Nanocrystal Characterization and 1D LSCs

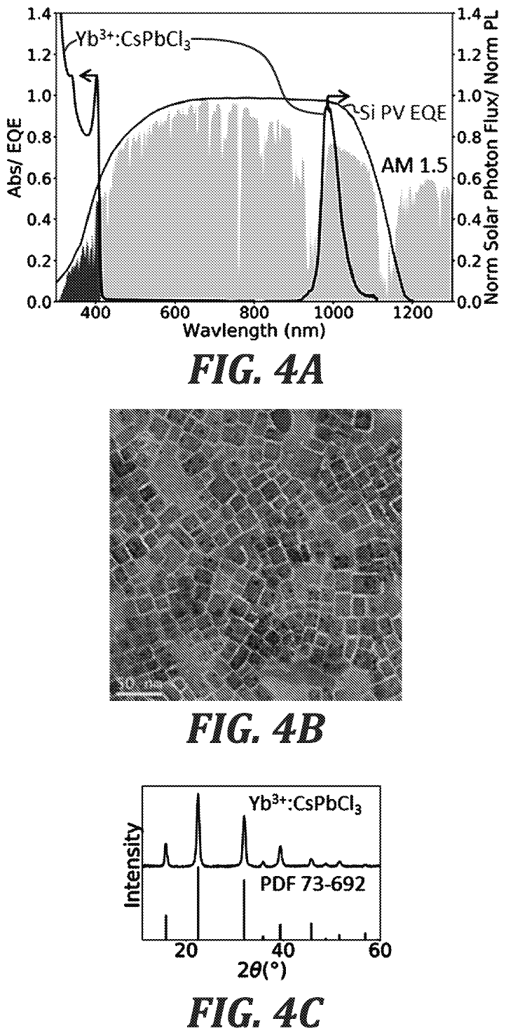

FIG. 4A shows representative absorption and PL spectra of Yb³⁺:CsPbCl₃ NCs dispersed in hexane, and compares these spectra with the external quantum efficiency (EQE) of a near infrared (NIR) enhanced Si HIT PV cell and the AM 1.5 solar spectrum. The analytical atomic Yb³⁺ B-site concentration for these NCs was 5.4%, and the PLQY was measured to be 130% at a CW excitation rate ˜350 s⁻¹. The NCs absorb UV light in a region where the Si PV EQE is poor, and they reemit this energy in a region where the Si PV EQE 1. FIG. 4B shows a representative TEM image of a sample of Yb³⁺:CsPbCl₃ NCs. The NCs display the characteristic cube-like shapes of the parent CsPbCl₃ NCs. FIG. 4C shows representative XRD data demonstrating that the perovskite crystal structure was indeed synthesized. The reproducibility of this synthesis was validated in our previous report.

Undoped perovskite NCs, thin films, and Mn²⁺-doped CsPbCl₃ NCs have been used in LSCs previously. Because the key attraction of LSCs is their ability to harvest photons over large LSC facial areas for concentration into small PV areas, it is important to evaluate the photon losses in larger waveguides, for example on the scale of a building's windows. To this end, measurements were performed here on Yb³⁺:CsPbCl₃ NCs in a large waveguide.

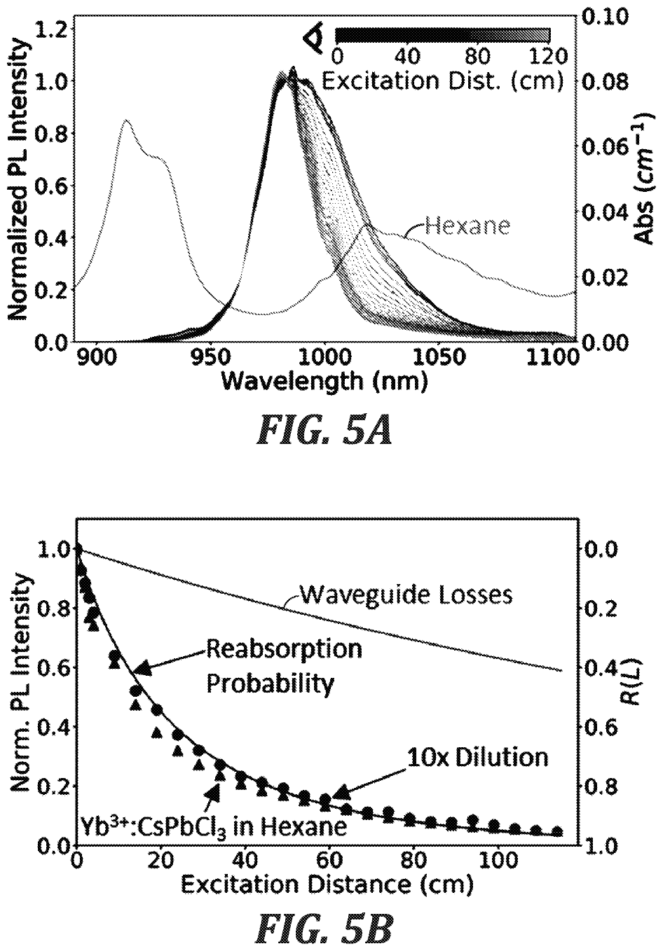

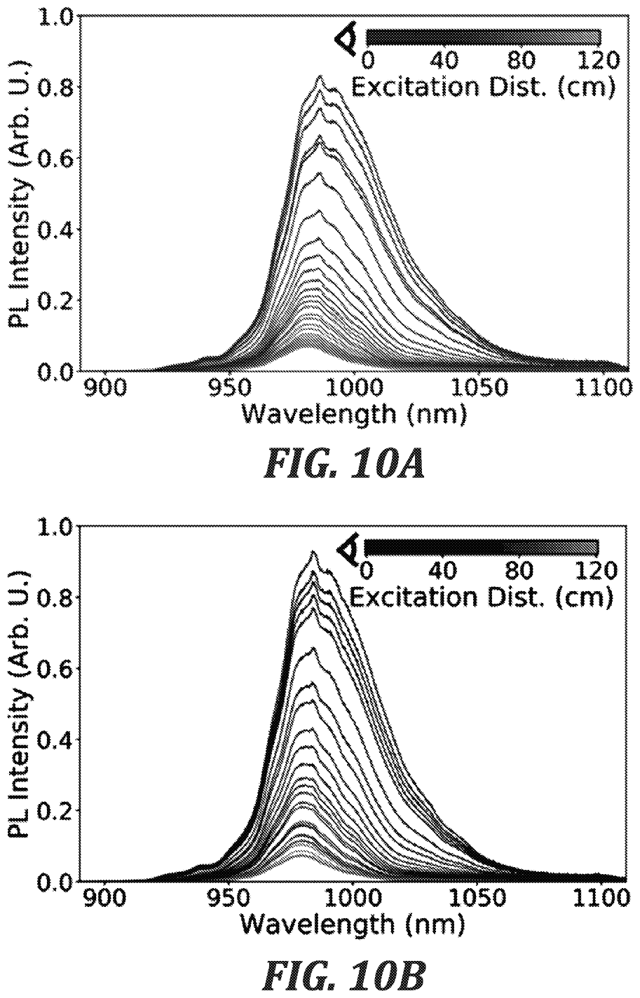

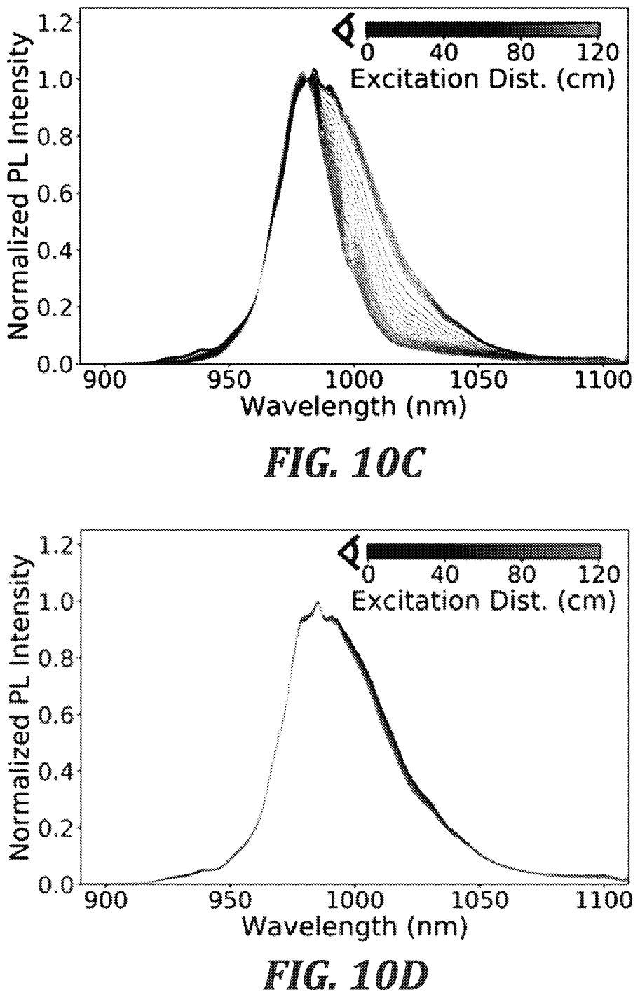

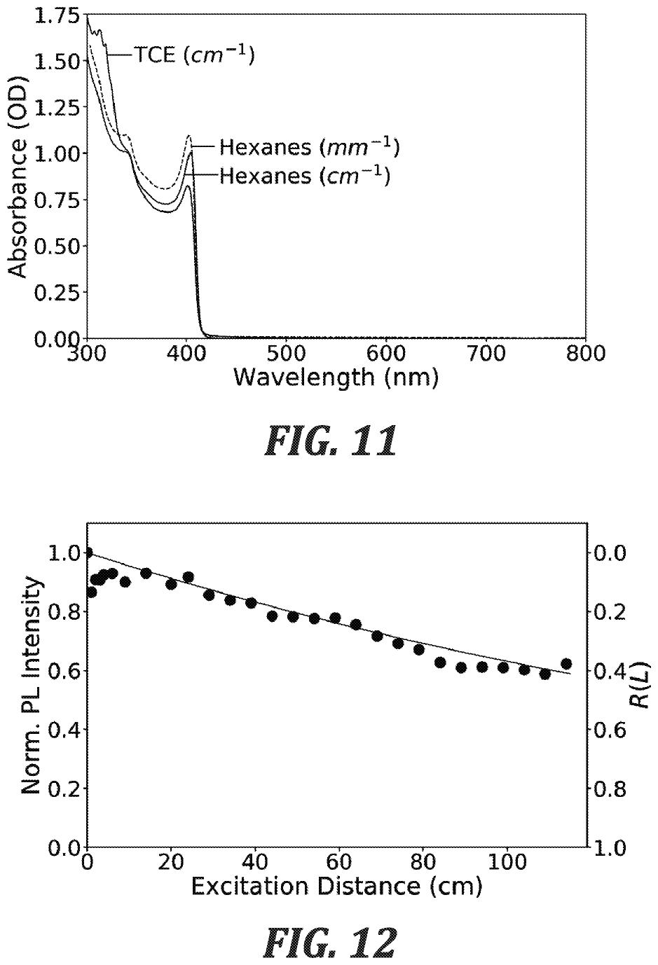

FIG. 5A plots normalized experimental PL spectra collected in a (120 cm)×(1 mm)² 1D LSC at various excitation distances away from the LSC edge, where the photodetector is mounted (complete PL intensity data are provided in FIGS. 10A-10D). For these measurements, Yb³⁺:CsPbCl₃ NCs were suspended in hexane with a transverse optical density (ODₜ) of ˜0.75 mm⁻¹ at 375 nm (FIG. 11). FIG. 5B plots the integrated intensities of the raw PL traces as a function of excitation distance, normalized to the integrated PL intensity at the shortest excitation distance. These data show substantial attenuation of the PL as the distance traveled by emitted photons to the detector through the waveguide is increased. For comparison, FIG. 5B also plots the experimentally determined waveguide attenuation over these extremely large waveguide lengths, reflecting photon scattering and otherwise imperfect transmission even in the absence of NCs. The curve plotted here was obtained by fitting the 1D LSC attenuation data (FIG. 12), which yielded a wavelength-independent attenuation coefficient of 0.002 cm⁻¹. This curve represents the performance limit of this particular 1D LSC waveguide, and it allows the intrinsic NC performance to be assessed. These results show that the experimental Yb³⁺ PL attenuation is not due to waveguide losses. As independent confirmation, FIG. 5B also plots analogous 1D LSC data collected for the same NCs diluted by a factor of 10. These LSC data are essentially indistinguishable from the higher-concentration data, indicating substantial attenuation that is not caused by the NCs themselves. Instead, this attenuation can be traced to absorption of the Yb³⁺ PL by vibrational bands of the organic medium containing the NCs in this 1D LSC. FIG. 5A also plots the absorption spectrum of hexane in the wavelength region of the Yb³⁺ PL and reveals a series of weak but significant vibrational overtone bands characteristic of C—H stretching vibrations. The data in FIG. 5A show that the Yb³⁺ PL intensity is attenuated on its red and blue edges with increasing waveguide length, precisely where this PL overlaps with these vibrational overtone bands.

For quantitative data analysis, these 1D LSC data were modeled following methods described, for example, in L. R. Bradshaw, K. E. Knowles, S. McDowall and D. R. Gamelin, Nano Lett., 2015, 15, 1315-1323, and K. E. Knowles, T. B. Kilburn, D. G. Alzate, S. McDowall and D. R. Gamelin, Chem. Commun., 2015, 51, 9129-9132, incorporated herein in their entireties. Briefly, the PL reabsorption probability is described by eq 1,

$$R ( L ) = \int P {L}_{n o r m} ( λ ) ( 1 - 1 {0}^{\frac{- {A}_{n o r m} ( λ ) L O {D}_{t}}{t}} ) d λ \qquad 1 )$$

where Aₙₒᵣₘ(λ) is the absorption spectrum of the NCs, solvent, and waveguide normalized at 375 nm, t is the thickness of the NC layer in the 1D LSC (t=1.0 mm here), ODₜ is the optical density over that thickness at the excitation wavelength of 375 nm, L is the excitation distance away from the LSC collection edge, and PLₙₒᵣₘ(λ) is the amplitude of the area-normalized NC PL spectrum measured at λ. Using eq 1, the hexane absorption spectrum, and the PL spectrum at L=0 from FIG. 5B, the attenuation of the integrated Yb³⁺ luminescence intensity as a function of L was simulated. The resulting curve is included in FIG. 5B along with the experimental data, and good agreement between the two is observed. Overall, this analysis confirms that the PL attenuation in this experiment is not due to losses involving the NCs or the glass portion of the waveguide, but instead comes from absorption of emitted photons by C—H vibrations of the organic portion of the waveguide, and it allows quantitative description of these contributions to the overall LSC performance.

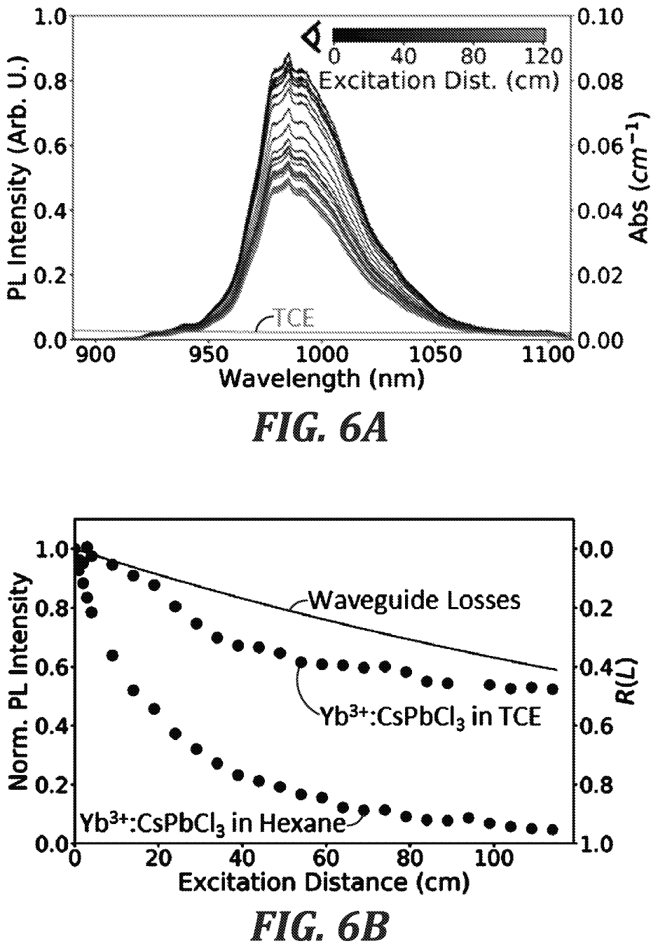

To eliminate the C—H absorption losses identified above, Yb³⁺:CsPbCl₃ NCs were suspended in tetrachloroethylene (TCE), which lacks protons and is therefore transparent in the NIR window of interest. FIG. 6A plots the Yb³⁺ PL intensity measured as a function of excitation distance for 1D LSC measurements with this solvent. For comparison, the corrected absorption spectrum of TCE is also included in FIG. 6A. Because TCE has no C—H vibrational overtone bands in the NIR, the Yb³⁺ PL intensity decay is now independent of wavelength. For comparison, FIG. 6B plots the integrated PL intensities vs excitation distance for the same NC concentration in both TCE and hexane (FIG. 11). The PL intensity from the TCE solution is substantially greater at large excitation distances than that from the hexane solution under similar conditions. In fact, the integrated PL intensity from the TCE solution essentially follows the waveguide losses of the 1D LSC alone, indicating that this decay now comes primarily from scattering within the glass waveguide. These NCs show reabsorption losses as low as any of the NCs measured previously over similar 120 cm waveguide lengths.

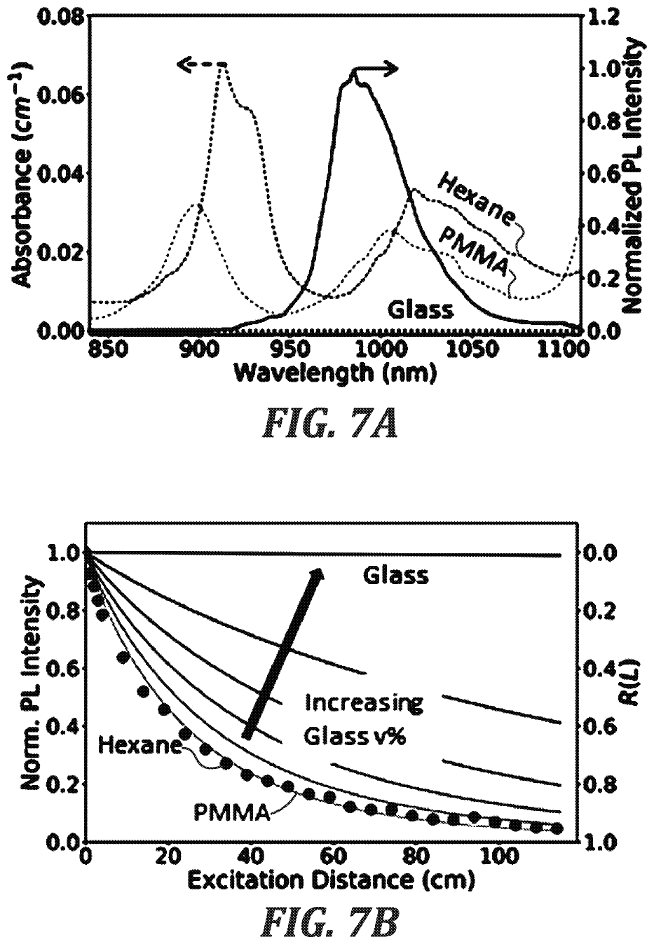

FIG. 7A shows the absorption spectra of hexane and two waveguide materials (PMMA and Schott optical-quality glass) overlaid with the Yb³⁺ PL spectrum from these Yb³⁺:CsPbCl₃ NCs. The PMMA spectrum shows C—H vibrational overtone absorption bands similar to those observed in hexane, shifted slightly to shorter wavelength and still overlapping the Yb³⁺ PL substantially. In contrast, the Schott glass shows little to no absorption in this region.

With these spectra, it is possible to simulate the performance of various acrylic and glass 1D LSCs, as well as of composite (or layered) waveguides involving different volume fractions of polymer and glass as per common 2D LSC configurations. An attenuation coefficient of 4.14×10^{0.5} cm⁻¹ was used to model transmission through glass in these simulations. FIG. 7B plots the results of these calculations. From these simulations, the NC performance in a PMMA waveguide will likely be as poor as the experimental 1D LSC results in hexane reported in FIG. 6B (reproduced in FIG. 7B for comparison). The results in FIG. 7A show that the PMMA absorbance itself is ˜0.02 cm⁻¹ where it overlaps the Yb³⁺ PL, and this absorption is not wavelength-independent. This analysis thus indicates that popular PMMA acrylics will likely not be suitable waveguide matrices for LSCs based on Yb³⁺ emission, including from quantum-cutting Yb³⁺:CsPb(Cl₁₋ₓBrₓ)₃ NCs. In contrast, the performance of Yb³⁺:CsPb(Cl₁₋ₓBrₓ)₃ NC LSCs using glass waveguides will likely be near the theoretical limit. FIG. 6B further illustrates that a device configuration involving a thin PMMA film containing densely packed NCs on top of a glass waveguide falls between these two extremes, with LSC performance determined by the relative PMMA and glass waveguide volumes. Clearly, this layered PMMA/glass LSC configuration is attractive with Yb³⁺:CsPb(Cl₁₋ₓBrₓ)₃ NCs if the PMMA film is very thin relative to the glass waveguide (e.g., <˜5% PMMA by volume).

2D LSCs

Monolayer 2D LSCs. 1D LSC data and simulations of the type presented above can help assess the 2D LSC performance of a given luminophore. The primary metric of interest is the LSC flux gain (FG), defined as the ratio of photons converted by a given LSC-coupled PV to photons that would be absorbed by the same PV exposed directly to the same solar flux. The 2D LSC flux gain (FG_{2D}) is calculated using eq 2,

$$F {G}_{2 D} = O Q E ( L ) \frac{{η}_{pl}}{{η}_{A M}} \frac{{A}_{n c}}{{A}_{sol}} G ( L ) \qquad 2 )$$

where η_{nc} is the NC PLQY, ηₚₗ/η_{AM} is the efficiency of a silicon PV exposed to the NC PL spectrum relative to the efficiency of the same PV exposed to AM 1.5 solar radiation. G(L) is the LSC geometric gain, equal to L/4t, where L is the edge length and t is the waveguide thickness in a square 2D device. The optical quantum efficiency OQE(L) is the ratio of photons that reach the LSC edge to solar photons absorbed by the LSC, A_{nc} is the solar flux absorbed by a particular NC LSC, and Aₛₒₗ is the solar flux absorbed by the solar cells coupled to the edges of the device when directly exposed to the solar irradiation. A_{nc} and Aₛₒₗ are calculated using eqs 3 and 4,

A_{nc}=∫Φ_{AM1.5}(λ)(1−10^{-A}^{_{abs}}^{(λ)})dλ 3)

Aₛₒₗ=∫Φ_{AM1.5}(λ)EQE(λ)dλ 4)

where Φ_{AM1.5} is the AM1.5 solar photon flux, A_{abs}(λ) is the NC absorption spectrum, EQE(λ) is the external quantum efficiency of the solar cell of interest. The 1D LSC results presented in FIG. 6B suggest that there are no reabsorption losses for the Yb³⁺:CsPbCl₃ layer. Therefore, OQE(L) can be calculated using eq 5.

$$OQE ( L ) = \frac{Φ}{4 π {L}^{2}} {\int \int }_{L \times L} {\int }_{0}^{2 π} {\int }_{{ϕ}_{e s c}}^{π - {ϕ}_{e s c}} {I}_{P L} ( l ( x , y , θ , ϕ ) ) sin ϕ d ϕ d θ dxdy \qquad 5 )$$

Here, l(x, y, θ, φ) is the distance a photon must travel from any point x, y∈[0, L], any azimuthal angle θ∈[0, 2π], and any polar angle φ∈[φ_{esc}, φ_{esc}−π], Φ is the NC PLQY, I_{PL} (L) is the normalized, integrated PL intensity as a function of excitation distance from a collection edge (obtained from the 1D LSC experimental data), and φ_{esc} is the polar angle that defines the photon escape cone, which equals are sin(1/n), where n is the waveguide's refractive index.

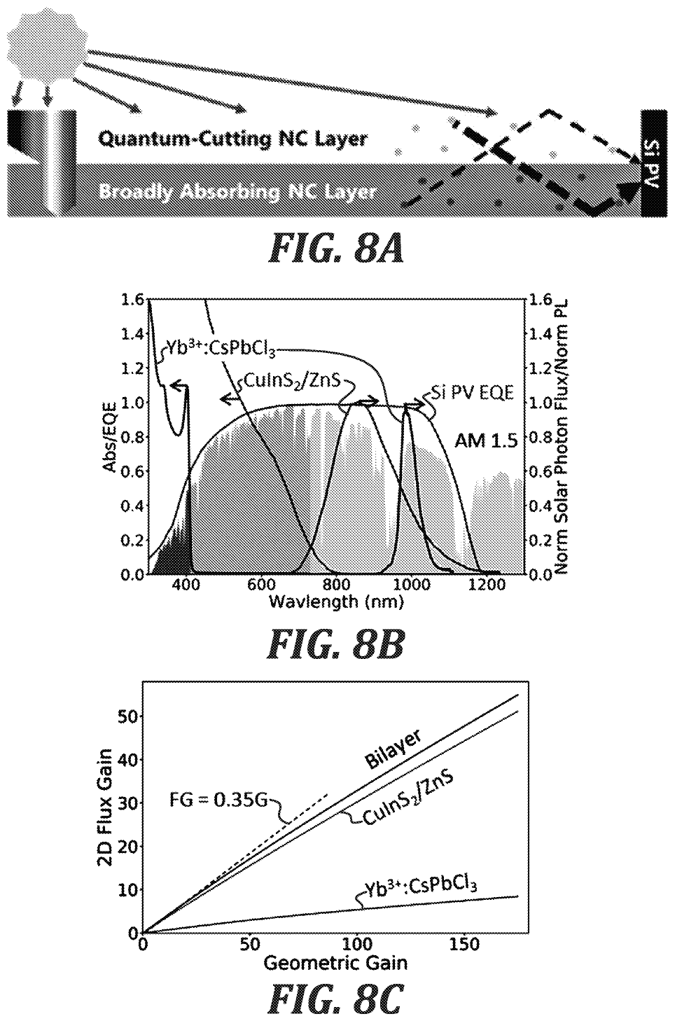

The flux gain of an Yb³⁺:CsPbCl₃ NC 2D LSC was calculated using eqs 2-5 using the experimental data from FIG. 6B as input (or extrapolated from these data for waveguiding lengths exceeding 120 cm). In this simulation, a value of =170% was used, based on experiment, and n was assumed to be 1.5, which is the approximate refractive index of glass or PMMA. Si HIT PV cells provide the best spectral matching with these Yb³⁺:CsPbCl₃ NCs, and these PV have ηₚₗ/η_{AM}˜1 because of their high NIR EQE. OQE(L) for the Yb³⁺:CsPbCl₃ NCs was calculated using eq 5. FIG. 8C (vide infra) summarizes the results of these simulations up to a geometric gain of 175. The initial slope of the flux gain trace for a Yb³⁺:CsPbCl₃ NC 2D LSC is 0.06, and the maximum projected flux gain is 8 at G=175. This value is substantially larger than the projected gain of 5 for a Zn_{0.87}Cd_{0.11}Mn_{0.02}Se/ZnS NC LSC simulated by the same methods as described, for example, in L. R. Bradshaw, K. E. Knowles, S. McDowall and D. R. Gamelin, Nano Lett., 2015, 15, 1315-1323, incorporated herein by reference in its entirety, despite the fact that Yb³⁺:CsPbCl₃ NCs absorb 30% fewer AM1.5 solar photons than Zn_{0.87}Cd_{0.11}Mn_{0.02}Se/ZnS NCs do. These results demonstrate that even with their wide energy gap, Yb³⁺:CsPbCl₃ NCs can excel as luminophores for 2D LSCs because of their exceptionally high PLQYs resulting from quantum-cutting.

CuInS₂ LSC Layer Modeling

The model described here was developed and validated in R. Sumner, S. Eiselt, T. B. Kilburn, C. Erickson, B. Carlson, D. R. Gamelin, S. McDowall and D. L. Patrick, J. Phys. Chem. C, 2017, 121, 3252-3260, incorporated herein by reference in its entirety. In this model, the fraction of absorbed photons attenuated by the waveguide, re-absorbed once by the NCs, and emitted into the escape cone are calculated separately using equations s1, s2, and s3, respectively.

$$\begin{matrix}ℱ = \frac{1}{4 π {L}^{2}} {\int \int }_{L \times L} {\int }_{0}^{2 π} {\int }_{{ϕ}_{e s c}}^{π - {ϕ}_{e s c}} \int P {L}_{norm} ( λ ) \frac{α}{α + {A}_{a b s} ( λ )} ( 1 - {e}^{- ( α - {A}_{a b s} ( λ ) ) l ( x , y , θ , ϕ )} ) d λ d ϕ d θ dxdy & ( s1 ) \\ ℛ = \frac{1}{4 π {L}^{2}} {\int \int }_{L \times L} {\int }_{0}^{2 π} {\int }_{{ϕ}_{e s c}}^{π - {ϕ}_{e s c}} \int P {L}_{norm} ( λ ) \frac{{A}_{a b s} ( λ )}{α + {A}_{a b s} ( λ )} ( 1 - {e}^{- ( α - {A}_{a b s} ( λ ) ) l ( x , y , θ , ϕ )} ) d λ d ϕ d θ dxdy & ( s2 ) \\ ɛ = 1 - \sqrt{1 - \frac{1}{{n}^{2}}} & ( s3 )\end{matrix}$$

Here, α is the attenuation of the waveguide (0.002 cm⁻¹). From here, the proportion of emitted photons that reach the edge of the LSC without being re-absorbed, attenuated, or emitted through the escape cone is [symbol] =1− [symbol] − [symbol] − [symbol] . To account for multiple cycles of re-absorption and emission, the OQE(L) of the CuInS₂ NC layer is calculated using an infinite series as follows:

$$OQE ( L ) = ℒ Φ {\sum }_{i = 0}^{∞} {( ℛΦ )}^{i} = \frac{ℒΦ}{1 - ℛ Φ} \qquad ( s4 )$$

Bilayer 2D LSCs. (i) Yb³⁺:CsPbCl₃/CuInS₂ bilayers. Although Yb³⁺:CsPbX₃ NC LSCs themselves have inherent advantages over other LSCs arising from their unusual quantum-cutting capabilities, the greatest advantage can be taken of these materials if they are paired with another set of narrower-gap NCs in the same waveguide to form a new type of monolithic bilayer LSC. FIG. 8A illustrates the proposed device structure. In this configuration, high-energy light is absorbed by the quantum-cutting Yb³⁺:CsPbCl₃ NCs. Lower-energy light is transmitted by the top layer and absorbed in the bottom layer, which may use any of several available broadband LSC luminophores. CuInS₂ and related NCs have emerged as particularly attractive materials for LSCs because of their high PLQYs, broadband absorption across the visible, and large effective PL Stokes shifts; for illustrative purposes, these are considered for the bottom layer of the proposed device. FIG. 8B plots relevant absorption and PL spectra for this device architecture. CuInS₂/ZnS NC absorption and PL spectra are reproduced from a recent report of high-performance NC LSCs. Importantly, although the Yb³⁺:CsPbCl₃ and CuInS₂/ZnS NCs are layered such that bluer photons are absorbed by the top-layer Yb³⁺:CsPbCl₃ NCs, and transmitted redder photons are absorbed by the bottom-layer CuInS₂/ZnS NCs, both layers emit in the NIR at wavelengths that can be transmitted through both absorber layers of this waveguide. Like two-terminal tandem LSCs investigated previously, this bilayer device structure improves LSC efficiency by eliminating thermalization losses associated with the blue photons. Unlike two-terminal tandem LSCs, however, this structure has the distinct advantage that it avoids the use of two separate LSCs that use separate PV cells wired in series. For maximum efficiency, the tandem configuration would require current matching between the two LSC layers. In the monolithic bilayer configuration, it is the currents that are added at the fixed voltage of the single edge-mounted PV, vastly simplifying the device.

To explore the potential benefits that might be expected from such a quantum-cutting bilayer LSC, the experimental data described above were used to model the performance of 2D Yb³⁺:CsPbCl₃ NC/CuInS₂ NC bilayer LSCs in the configuration illustrated in FIG. 8A. The flux gains of Yb³⁺:CsPbCl₃/CuInS₂ NC-based bilayer 2D LSCs were calculated using eqs 2-5. In these simulations, a value of =91% was used for the for CuInS₂ NCs, based on the highest reported literature value (obtained with CuInS₂/ZnS core/shell NCs), described, for example, in M. R. Bergren, N. S. Makarov, K. Ramasamy, A. Jackson, R. Guglielmetti and H. McDaniel, ACS Energy Lett., 2018, 3, 520-52, incorporated herein by reference in its entirety. ηₚₗ/η_{AM} was again assumed to be ˜1 due to the high NIR EQE of the Si HIT cells. For CuInS₂ NCs, an additional OD of 0.002 cm⁻¹ was added to the attenuation spectrum to simulate the impact of waveguide losses on the projected flux gain. Because reabsorption losses will affect the performance of the CuInS₂ layer, the OQE(L) of the CuInS₂ layer is computed using an advanced analytical model. A detailed description of this model is provided below.

To simulate the performance of the bilayer LSC of FIG. 8A, the thickness of each waveguide layer was assumed to be 0.5 mm and the optical density of each layer was doubled compared to its single-layer analog. From here, the solar flux absorbed by the CuInS₂ NCs in the bilayer device is the difference between A_{CIS} and A_{CsPbCl}_{₃}. Once this modification is made, the flux gain of the bilayer device is simply the sum of the Yb³⁺:CsPbCl₃ NC LSC flux gain and the CuInS₂ NC LSC flux gain. FIG. 8C summarizes the results of these simulations. The bilayer device reaches a flux gain of 55 for G=175, which is a 7% improvement over the CuInS₂ NC LSC of similar dimensions. The initial slope of the bilayer device is 0.35, compared with 0.06 for the Yb³⁺:CsPbCl₃ NC LSC or 0.32 for the CuInS₂ NC LSC alone.

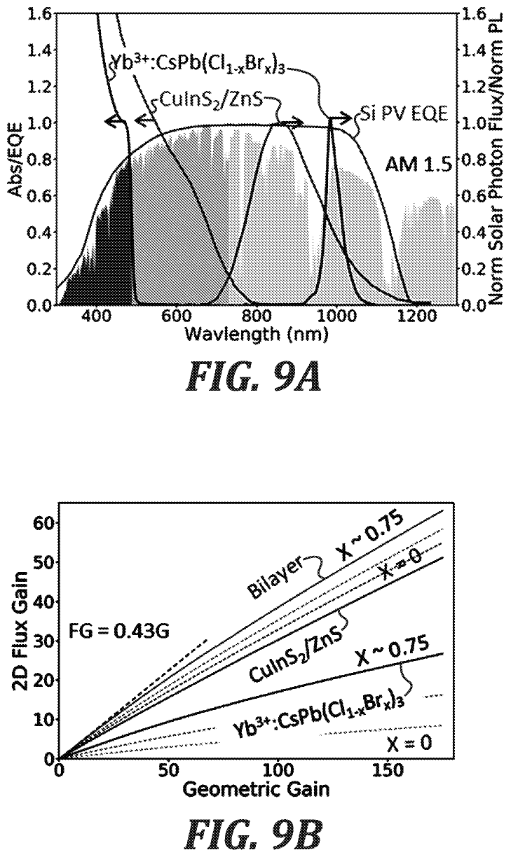

Yb³⁺:CsPb(Cl₁₋ₓBrₓ)₃/CuInS₂ bilayers. Improved solar absorption can be achieved by narrowing the top layer's energy gap through anion alloying. FIG. 9A shows the absorption and PL spectra of Yb³⁺:CsPb(Cl₁₋ₓBrₓ)₃ NCs synthesized from Yb³⁺:CsPbCl₃ NCs via anion exchange. Increasing x to ˜0.75 decreases the NC energy gap to ˜488 nm (˜2.5 eV) and increases the fraction of the solar spectrum absorbed from ˜2.6% (x=0) to ˜8.3% without impacting the PLQY of the Yb³⁺ emission. FIG. 9B plots the results of this model for three values of the perovskite absorption threshold, from 412 nm (x=0) to 488 nm (x˜0.75), calculated by modifying A_{CsPb(Cl}_{₁₋ₓ}_{Br}_{ₓ}₎_{₃} in eq 3. Narrowing the perovskite energy gap increases the initial flux-gain slope of the stand-alone Yb³⁺:CsPb(Cl₁₋ₓBrₓ)₃ NC LSC from 0.06 to 0.20 and increases the flux-gain to 27 at G=175. The initial flux-gain slope of the bilayer device increases from 0.35 to 0.43 and the flux gain increases to 63 at G=175. This result means that for the modeled 70×70×0.1 cm³ monolithic bilayer LSC, the 28 cm² of Si solar cells optically coupled to its edges are predicted to generate 63 times more current than when the same solar cells are operating in non-concentrating conditions. These results represent a 19% performance increase compared with state-of-the-art CuInS₂ NC LSCs. The percentage improvement will be even greater if the PLQY of the CuInS₂ NC layer is not the record 91% but closer to the ˜70% typically found for CuInS₂ NC/polymer composites.

The CuInS₂ NCs modeled above were likely optimized for a polycrystalline Si PV, whereas narrower-gap CuIn(S_{1-y}Se_{y})₂ NCs may be more appropriate for the Si HIT PV simulated here. To assess the effect of increasing solar absorbance through this change, the performance of the same bilayer LSC was modeled but using the absorption and emission spectra of QD-950 from the Strem catalog. Although the solar absorbance of the QD-950 NCs does increase from 26% to 38%, the flux gain of the Yb³⁺:CsPb(Cl₁₋ₓBrₓ)₃ NC monolithic bilayer device decreases, e.g., from 63 to 54 at G=175, despite again assuming a PLQY of 91%. This lack of improvement was attributed to increased reabsorption losses in the QD-950 NCs because of their more pronounced absorption tail. Nonetheless, the flux gain of the monolithic bilayer LSC involving a QD-950 NC bottom layer is improved by 35% over the optimized QD-950 NC 2D LSC alone, again validating the bilayer LSC configuration as a simple and attractive opportunity for next-generation NC LSCs.

The experimental results described above demonstrate superb performance of Yb³⁺-doped halo-perovskite NCs as zero-reabsorption luminophores for large-scale LSCs. Their experimental losses in a 1D LSC are almost completely negligible over extremely large waveguide lengths of up to 120 cm. Moreover, these Yb³⁺:CsPbCl₃ NCs display the unusual and extremely attractive characteristic of quantum-cutting, by which PLQYs vastly exceeding 100% have been measured. As demonstrated experimentally in FIGS. 5-7, however, the PL of these quantum-cutting NCs is absorbed by overtones of high-frequency proton-stretching vibrations present in common LSC polymer matrices. This works shows that to succeed, an LSC based on Yb³⁺-doped NCs must use a waveguide matrix that contains very few protons in the form of C—H, O—H, or related bonds. NC LSCs using fluorinated waveguides are viable. Alternatively, all-inorganic waveguides such as the oxide matrices used for Nd³⁺ LSCs are also attractive; a notable proof-of-concept is found in the examples of colored Schott glasses

Through a combination of experimental and computational studies, Yb³⁺:CsPb(Cl₁₋ₓBrₓ)₃ NCs are shown to serve as a unique LSC luminophore due to their large effective Stokes shift and extraordinarily high PLQY (approaching 200%), arising from their efficient quantum-cutting PL mechanism. These NCs have the lowest self-absorption of any NCs investigated to date, comparable to Mn²⁺-doped II-VI NCs, but with overall LSC performance exceeding that of the Mn²⁺-doped NCs because of their very high PLQYs. The experimental measurements presented here show that proton-free waveguide matrices can be advantageous in LSCs involving these luminophores. Finally, a monolithic bilayer LSC device architecture containing quantum-cutting Yb³⁺:CsPb(Cl₁₋ₓBrₓ)₃ NCs in its top layer and, e.g., CuInS₂/ZnS NCs in its bottom layer was modeled. This bilayer design uses quantum-cutting to increase photocurrent rather than using multiple PV energy gaps to increase photovoltage. As such, this bilayer device has the distinct advantage that PL from both the top (blue-absorbing) and bottom (red-absorbing) luminescent layers can be transported through the same waveguide to the same Si PV, obviating the need for multiple PV cells, interlayer wiring, and current matching as found in traditional tandem devices. Such advantages simplify device construction and operation. A bilayer LSC using Yb³⁺:CsPb(Cl_{0.25}Br_{0.75})₃ NCs for the top layer could improve upon the performance of an idealized state-of-the-art CuInS₂/ZnS NC LSC bottom layer by at least 19%.

While illustrative embodiments have been illustrated and described, it will be appreciated that various changes can be made therein without departing from the spirit and scope of the invention.

1. A luminescent solar concentrator, comprising:
a layer comprising a quantum-cutting material; and
a layer comprising a broadly light-absorbing material optically coupled to and beneath the layer comprising the quantum-cutting material, wherein the broadly light-absorbing material has a red-shifted absorption onset compared to the absorption onset of the quantum-cutting material.

2. The luminescent solar concentrator of claim 1, further comprising a light-utilization device in optical communication with an edge of the luminescent solar concentrator.

3. The luminescent solar concentrator of claim 2, wherein the absorption onset of the coupled light-utilization device is lower in energy than the emission maximum of the luminescent solar concentrator, wherein at least 50% of the emitted light is above the absorption onset of the light-utilization device.

4. The luminescent solar concentrator of claim 1, wherein the quantum-cutting material has an absorption onset energy at least two times the emission energy of the quantum-cutting material.

5. The luminescent solar concentrator of claim 1, wherein the layer comprising a broadly light-absorbing material further comprises one or more additional broadly light-absorbing materials, each having a red-shifted absorption onset compared to the absorption onset of the quantum-cutting material.

6. The luminescent solar concentrator of claim 1, further comprising one or more additional layers beneath the layer comprising the broadly light-absorbing material, each additional layer optically coupled to an adjacent preceding layer and comprising a different broadly light-absorbing material compared to the adjacent preceding layer.

7. (canceled)

8. The luminescent solar concentrator of claim 1, wherein the emission wavelength range of the quantum-cutting material and the absorption wavelength range of the one or more broadly light-absorbing materials combined have an overlap characterized in that at least 50% of the light emitted by the quantum-cutting material is not absorbed by the broadly light-absorbing materials over a distance of 10 cm in the luminescent solar concentrator.

9. The luminescent solar concentrator of claim 1, wherein the absorption wavelength range of the quantum-cutting material and the absorption wavelength range of the one or more broadly light-absorbing materials overlap at wavelengths shorter than the absorption onset of the quantum-cutting material.

10. The luminescent solar concentrator of claim 2, wherein the light-utilization device comprises a photovoltaic cell.

11. (canceled)

12. The luminescent solar concentrator of claim 1, wherein the quantum-cutting material comprises a composition of formula Yb³⁺:CsPb(Cl₁₋ₓBrₓ)₃, wherein x is greater than or equal to 0 and less than or equal to 0.9.

13. The luminescent solar concentrator of claim 1, wherein the quantum-cutting material has a chemical formula selected from the group of formulae consisting of:
M:ABX₃,
M:AB₂X₅,
M:A₄BX₆,
M:C₂DX₅,
M:A₂CDX₆, and
combinations thereof,
wherein,
A is a cation selected from the group consisting of Li⁺, Na⁺, K⁺, Rb⁺, Cs⁺, methylammonium (MA), formamidinium (FA), guanidinium, dimethylammonium, trimethylammonium, and combinations thereof,
B is a cation selected from the group consisting of Pb²⁺, Sn²⁺, Ge²⁺, Cd²⁺, Mg²⁺, Ti²⁺, Hg²⁺, and combinations thereof,
C is a cation selected from the group consisting of Ag⁺, Cu⁺, Sn⁺, Na⁺, K⁺, Tl⁺, Au⁺, and combinations thereof,
D is a cation selected from the group consisting of In³⁺, Bi³⁺, Sb³⁺, Au³⁺, and combinations thereof,
X is an anion selected from the group consisting of O⁻, F⁻, Cl⁻, Br⁻, I⁻ CN⁻, and combinations thereof, and
M is a cation selected from the group consisting of Y³⁺, La³⁺, Ce³⁺, Pr³⁺, Nd³⁺, Pm³⁺, Sm³⁺, Eu³⁺, Gd³⁺, Tb³⁺, Dy³⁺, Ho³⁺, Er³⁺, Tm³⁺, Yb³⁺, Lu³⁺, Sc³⁺, Fe³⁺, Al³⁺, V²⁺, Cr²⁺, Mn²⁺, Bi³⁺, and combinations thereof.

14. The luminescent solar concentrator of claim 1, wherein the broadly light-absorbing material comprises CuIn(Se₁₋ₓSₓ)₂ (0≤x≤1) nanocrystals, CuInS₂ nanocrystals, Cu⁺:CdSeₓTe₁₋ₓ (0≤x≤1) nanocrystals, Cu⁺:PbSₓSe₁₋ₓ (0≤x≤1) nanocrystals, Cu⁺:InP Yb³⁺:CdSeₓTe₁₋ₓ (0≤x≤1) nanocrystals, Yb³⁺:PbSₓSe₁₋ₓ (0≤x≤1) nanocrystals, Yb³⁺:InP nanocrystals, CdSeₓTe₁₋ₓ/Cd_{y}Zn_{1-y}S_{z}Se_{1-z} (0≤x≤1, 0≤y≤1, and 0≤z≤1) core/shell nanocrystals, InP/ZnO core/shell nanocrystals, PbSₓSe₁₋ₓ/Cd_{y}Zn_{1-y}S_{z}Se_{1-z} (0≤x≤1, 0≤y≤1, and 0≤z≤1) core/shell nanocrystals, CdSe/CdS dot-in-rod structures, perylene, rhodamine 6G, platinum tetraphenyltetrabenzoporphyrin (Pt(TPBP)), 4-(dicyanomethylene)-2-tert-butyl-6-(1,1,7,7-tetramethyljulolidin-4-yl-vinyl)-4H-pyran (DCJTB), Lumogen F Red 305, derivatives thereof, or any combination thereof.

15. The luminescent solar concentrator of claim 1, wherein the broadly light-absorbing material has a chemical formula selected from the group of formulae consisting of:
M:ABX₃,
M:AB₂X₅,
M:A₄BX₆,
M:C₂DX₅,
M:A₂CDX₆, and
combinations thereof,
wherein,
A is a cation selected from the group consisting of Li⁺, Na⁺, K⁺, Rb⁺, Cs⁺,
methylammonium (MA), formamidinium (FA), guanidinium, dimethylammonium,
trimethylammonium, and combinations thereof,
B is a cation selected from the group consisting of Pb²⁺, Sn²⁺, Ge²⁺, Cd²⁺, Mg²⁺, Ti²⁺, Hg²⁺, and combinations thereof,
C is a cation selected from the group consisting of Ag⁺, Cu⁺, Sn⁺, Na⁺, K⁺, Tl⁺, Au⁺, and combinations thereof,
D is a cation selected from the group consisting of In³⁺, Bi³⁺, Sb³⁺, Au³⁺, and combinations thereof,
X is an anion selected from the group consisting of O⁻, F⁻, Cl⁻, Br⁻, I⁻ CN⁻, and combinations thereof, and
M is a cation selected from the group consisting of Y³⁺, La³⁺, Ce³⁺, Pr³⁺, Nd³⁺, Pm³⁺, Sm³⁺, Eu³⁺, Gd³⁺, Tb³⁺, Dy³⁺, Ho³⁺, Er³⁺, Tm³⁺, Yb³⁺, Lu³⁺, Sc³⁺, Fe³⁺, Al³⁺, V²⁺, Cr²⁺, Mn²⁺, Bi³⁺, and combinations thereof.

16. (canceled)

17. The luminescent solar concentrator of claim 1, wherein the quantum-cutting material is in the form of particles suspended in a waveguiding material.

18. (canceled)

19. The luminescent solar concentrator of claim 1, wherein at least one of the broadly light-absorbing material is in the form of particles suspended in a waveguiding material.

20. (canceled)

21. The luminescent solar concentrator of claim 1, wherein the quantum-cutting material is deposited onto a waveguiding material and is optically coupled to the waveguiding material, or at least one of the broadly light-absorbing material is deposited onto a waveguiding material and is optically coupled to the waveguiding material.

22-23. (canceled)

24. The luminescent solar concentrator of claim 6, wherein one or more additional layers comprise a waveguide material selected from the group consisting of a polyacrylate, a polycarbonate, an inorganic glass, a quartz, a polycrystalline solid, an amorphous solid, a cyclic perfluorinated polyether, a polysilicone, a polysiloxane, a polyalkylacrylate, a cyclic olefin.

25. (canceled)

26. The luminescent solar concentrator of claim 1, further comprising a layer selected from a bragg, short-pass, long-pass, or broadband mirror.

27. An article, comprising the luminescent solar concentrator of claim 1.

28. The luminescent solar concentrator of claim 27, wherein the article is selected from a window pane, a coating, and an electronic display.
